(19) United States
(12) Patent Application Publication
(10) Pub. No.: US 2026/0323184 A1
(43) Pub. Date: Oct. 15, 2026

(54) PHOTODETECTION ELEMENT AND ELECTRONIC APPARATUS

(71) Applicant: Sony Semiconductor Solutions Corporation, Kanagawa (JP)

(72) Inventors: Takeshi Ohkawa, Kanagawa (JP); Takeshi Oyakawa, Tokyo (JP); Akihiro Watanabe, Kanagawa (JP); Akito Sekiya, Kanagawa (JP); Dan Luo, Kanagawa (JP)

(21) Appl. No.: 19/114,626

(22) PCT Filed: Sep. 29, 2023
(86) PCT No.: PCT/JP23/35566

§ 371 Date: Mar. 24, 2025

(30) Foreign Application Priority Data
Oct. 19, 2022 (JP) 2022-167290

(51) Int. Cl. H04N 25/773

(52) U.S. Cl. CPC H04N 25/773

(57) ABSTRACT

Photodetection elements with suppressed decrease in measurement accuracy due to temperature change are disclosed. In one example, a photodetection element includes a photodiode that photoelectrically converts incident light and outputs a photocurrent; and a control circuit that performs control to change a potential of one end of the photodiode according to a temperature related to the photodiode.

### TECHNICAL FIELD

The present disclosure relates to a photodetection element and an electronic apparatus.

### BACKGROUND ART

Conventionally, in an electronic apparatus having a ranging function, a ranging method called a time of flight (ToF) method is known. The ToF method is a method of measuring a distance by irradiating an object with irradiation light from an electronic device and obtaining a round-trip time until the irradiation light is reflected and returned to the electronic device. For example, a ToF type camera that detects reflected light by a single-photon avalanche diode (SPAD) has been proposed. The SPAD is a photodiode with improved sensitivity by amplifying photocurrent.

The SPAD is used in a Geiger mode in which a reverse bias is applied to a voltage equal to or higher than a certain voltage. In this Geiger mode, control is performed such that a constant potential is applied in a state where a power source is applied to the anode side and a resistance or a constant current is applied to the cathode side.

### CITATION LIST

### Patent Document

Patent Document 1: Japanese Patent Application Laid-Open No. 2019-75394

### SUMMARY OF THE INVENTION

### Problems to be Solved by the Invention

However, in the SPAD, even when a constant potential is applied to the anode side, the voltage between the anode and the cathode varies depending on the temperature. For this reason, the voltage between the anode and the cathode varies, and the measurement accuracy may decrease.

The present disclosure provides a photodetection element and an electronic apparatus capable of suppressing a decrease in measurement accuracy due to a temperature change.

### Solutions to Problems

In order to solve the above problem, according to the present disclosure, there is provided a photodetection element including: a photodiode that photoelectrically converts incident light and outputs a photocurrent; and a control circuit that performs control to change a potential of one end of the photodiode according to a temperature related to the photodiode.

The control circuit may supply a lower potential to an anode of the photodiode as the temperature is higher.

The photodiode may be a SPAD operable in a Geiger mode, the photodetection element may further include a resistor having one end connected to a cathode of the photodiode, and a predetermined potential may be supplied to an other end of the resistor.

A temperature detection circuit that detects the temperature is further included, and the control circuit may control the potential according to the temperature detected by the temperature detection circuit.

A resistor having one end connected to a cathode of the photodiode is further included, and control may be performed in: a first mode of controlling the potential according to the temperature; and a second mode of supplying a lower potential to an anode of the photodiode as a bottom potential of the cathode is higher when the photocurrent flows through the resistor.

The potential may be controlled in the first mode up to a predetermined number of times after supplying the potential to the anode of the photodiode is stopped.

The control circuit may control the potential in the second mode after the potential is controlled in the first mode.

The control circuit may control the potential in the first mode in a case where a predetermined potential in the cathode cannot be detected.

An arithmetic circuit that calculates the potential according to the temperature is further included, and the control circuit may control the potential on the basis of a calculation result of the arithmetic circuit.

The arithmetic circuit may calculate the potential according to a predetermined coefficient and the temperature.

The arithmetic circuit may calculate the potential also on the basis of a difference value between an initial bottom potential of the cathode, which is a potential when control in the second mode has started, and a target potential.

The arithmetic circuit may calculate the potential on the basis of a fluctuation of the temperature per predetermined time.

A detection circuit is further included which detects a minimum value of the cathode when the photocurrent flows through the resistor as the bottom potential and supplies the detected minimum value to the arithmetic circuit.

The detection circuit may include a smoothing circuit that performs smoothing calculation including a predetermined number of the bottom potentials before imaging, and a predetermined number of times of imaging in the first mode may correspond to a predetermined number before the imaging.

The predetermined number of times of imaging in the first mode may be one at a time of activation.

A pixel array unit in which a plurality of pixel circuits each including the resistor and the photodiode is arranged in a two-dimensional matrix is further included, at least two of the temperature detection circuits may be configured at different positions of an element in which the pixel array unit is configured, and the control circuit may perform control to change a potential of one end of each photodiode in a plurality of pixel circuits on the basis of each temperature detected by each of the temperature detection circuits.

A pixel array unit in which a plurality of pixel circuits each including the resistor and the photodiode is arranged in a two-dimensional matrix is further included, each of at least two pixel circuits among the plurality of pixel circuits may include the detection circuit, and the control circuit may perform control to change a potential of one end of each photodiode in a plurality of pixel circuits on the basis of each potential detected by the detection circuit.

The arithmetic circuit and the control circuit may be integrally configured in a same element.

A power source circuit is further included which supplies a potential of the anode of each of the plurality of pixel circuits, and the control circuit may control the power source circuit.

According to the present disclosure, an electronic apparatus is provided which includes a photodetection element and a light emitting unit configured to emit measurement light synchronized with a timing of changing the potential.

### BRIEF DESCRIPTION OF DRAWINGS

FIG. 1 is a block diagram illustrating a configuration example of a ranging module according to a first embodiment of the present technology.

FIG. 2 is a block diagram illustrating a configuration example of a photodetection element according to the first embodiment of the present technology.

FIG. 3 is a diagram illustrating a configuration example of a pixel array unit and a control circuit according to the present embodiment.

FIG. 4 is a diagram illustrating a circuit configuration example of an imaging pixel circuit.

FIG. 5 is a diagram illustrating temperature characteristics when a constant anode potential is applied to an anode of a photodiode.

FIG. 6 is a diagram illustrating an example of temperature characteristics of a cathode potential.

FIG. 7 is a diagram illustrating a control example of an anode potential of a photodiode of a control circuit.

FIG. 8 is a circuit diagram illustrating a configuration example of a control circuit.

FIG. 9 is a diagram illustrating a control operation example of a photodetection element.

FIG. 10 is a diagram illustrating a control operation example of a photodetection element in a case where a temperature monitor value is not used as a comparative example.

FIG. 11 is a circuit diagram illustrating a configuration example of a monitor pixel circuit and a VBD monitor circuit.

FIG. 12 is a diagram illustrating an example of operation characteristics of a VBD monitor circuit.

FIG. 13 is a diagram illustrating an example of operation characteristics of a VBD monitor circuit in a case where a temperature monitor value is not used at a high temperature.

FIG. 14 is a diagram illustrating a temporal change of a cathode potential in a case where a temperature monitor value is not used at a high temperature.

FIG. 15 is a diagram illustrating an example of operation characteristics of a VBD monitor circuit in a case where a temperature monitor value is not used at a low temperature.

FIG. 16 is a diagram illustrating a temporal change of a cathode potential in a case where a temperature monitor value is not used at a low temperature.

FIG. 17 is a flowchart illustrating an operation example of the photodetection element according to the present embodiment.

FIG. 18 is a diagram illustrating a configuration example of a pixel array unit and an arithmetic circuit 3 according to a first modification of the first embodiment.

FIG. 19 is a diagram illustrating a configuration example of a pixel array unit and an arithmetic circuit according to a second modification of the first embodiment.

FIG. 20 is a block diagram illustrating a configuration example of a pixel array unit according to a second embodiment.

FIG. 21 is a diagram illustrating a temporal change of a cathode potential Vc and an anode potential of a photodiode.

FIG. 22 is a diagram illustrating an example of temperature characteristics of the cathode potential Vc.

FIG. 23 is a flowchart illustrating an operation example of the photodetection element according to the second embodiment.

FIG. 24 is a diagram illustrating a configuration example of an imaging element according to the second embodiment.

FIG. 25 is a block diagram illustrating a configuration example of a pixel array unit according to a third embodiment.

FIG. 26 is a diagram illustrating a temporal change of a cathode potential Vc, an anode potential, and a temperature of a photodiode.

FIG. 27 is a diagram illustrating an operation example of the photodiode in a case where a temperature change occurs.

FIG. 28 is a diagram illustrating a configuration example of an imaging element according to the second embodiment.

FIG. 29 is a block diagram illustrating a configuration example of a ranging module according to a fourth embodiment.

FIG. 30 is a diagram illustrating a relationship between an anode-cathode voltage and pixel sensitivity of an imaging pixel circuit.

FIG. 31 is a diagram illustrating a relationship between an anode-cathode voltage and a distance error of an imaging pixel circuit.

FIG. 32 is a diagram illustrating a configuration example of a photodetection element according to the fourth embodiment.

FIG. 33 is a diagram illustrating an example in which control is performed with all flags set to 1 except at the time of activation.

FIG. 34 is a diagram illustrating an example in which control using a temperature T is performed in a case where a VBD monitor circuit does not function.

FIG. 35 is a diagram illustrating a configuration example of a VBD monitor circuit 2 according to the fourth embodiment.

FIG. 36 is a flowchart illustrating an example of control processing during a measurement operation according to the present embodiment.

FIG. 37 is a diagram illustrating a configuration example of a pixel array unit and a control circuit according to a first modification of the fourth embodiment.

FIG. 38 is a diagram illustrating a configuration example of a pixel array unit and a control circuit according to a second modification of the fourth embodiment.

FIG. 39 is a diagram illustrating an example of a circuit configuration of a VBD monitor circuit 2 according to a fifth embodiment.

FIG. 40 is a diagram illustrating a change in a VBD monitor value in a case where a reaction number threshold is set to 1 time.

FIG. 41 is a diagram illustrating a change in a VBD monitor value with a reaction number threshold (slightly bright environment) set to 1 time.

FIG. 42 is a diagram illustrating a change in a VBD monitor value in a case where the reaction number threshold is set to 4 times.

FIG. 43 is a diagram illustrating a change in a VBD monitor value in a case where the reaction number threshold (slightly bright environment) is set to 4 times.

FIG. 44 is a flowchart illustrating an example of control processing during a measurement operation in the fifth embodiment.

FIG. 45 is a block diagram illustrating a configuration example of a photodetection element according to a sixth embodiment of the present technology.

FIG. 46 is a flowchart illustrating an example of control processing according to the sixth embodiment.

FIG. 47 is a block diagram illustrating a configuration example of a photodetection element in a first modification of the sixth embodiment.

FIG. 48 is a block diagram illustrating a configuration example of a photodetection element according to a second modification of the sixth embodiment.

FIG. 49 is a block diagram illustrating a configuration example of an optical pixel array unit in a seventh embodiment of the present technology.

FIG. 50 is a block diagram illustrating a configuration example of a photodetection element according to an eighth embodiment.

FIG. 51 is a diagram illustrating an arrangement example of a temperature monitor circuit and a VBD monitor circuit according to the sixth embodiment.

FIG. 52 is a diagram illustrating an arrangement example of a temperature monitor circuit and a VBD monitor circuit according to a ninth embodiment.

FIG. 53 is a diagram illustrating a configuration example of a pixel array unit according to the ninth embodiment.

FIG. 54 is a block diagram illustrating a configuration example of a pixel array unit according to a tenth embodiment.

FIG. 55 is a block diagram illustrating a configuration example of a pixel array unit according to an eleventh embodiment.

FIG. 56 is a block diagram illustrating an example of a schematic configuration of a vehicle control system.

FIG. 57 is an explanatory diagram illustrating an example of installation positions of an outside-vehicle information detecting section and an imaging section.

### MODE FOR CARRYING OUT THE INVENTION

Hereinafter, embodiments of a photodetection element and an electronic apparatus will be described with reference to the drawings. Hereinafter, main components of the photodetection element and the electronic apparatus will be mainly described, but the photodetection element and the electronic apparatus may have components and functions that are not illustrated or described. The following description does not exclude components and functions that are not depicted or described.

### First Embodiment

### Configuration Example of Ranging Module

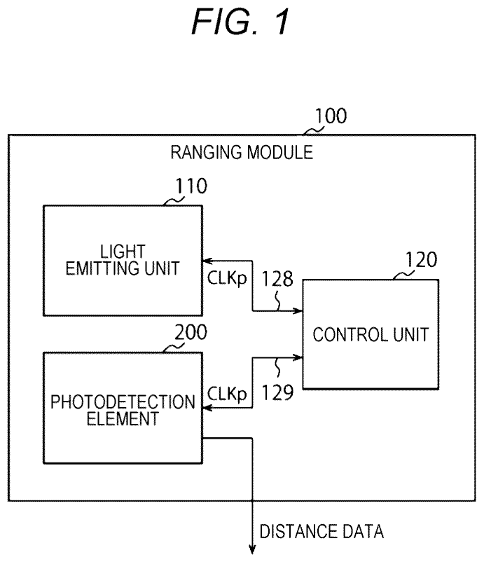

FIG. 1 is a block diagram illustrating a configuration example of a ranging module 100 according to a first embodiment of the present technology. The ranging module 100 measures a distance to an object, and includes a light emitting unit 110, a control unit 120, and a photodetection element 200. The ranging module 100 is mounted on an electronic apparatus such as a smartphone, a personal computer, or an in-vehicle device, and is used to measure a distance.

The control unit 120 controls the entire ranging module 100. For example, the control unit 120 operates the light emitting unit 110 and the photodetection element 200 in synchronization. The control unit 120 supplies a clock signal of a predetermined frequency (such as 10 to 20 megahertz) as a light emission control signal CLKp to the light emitting unit 110 and the photodetection element 200 via signal lines 128 and 129.

The light emitting unit 110 supplies intermittent light as irradiation light in synchronization with the light emission control signal CLKp from the control unit 120. For example, near-infrared light or the like is used as the irradiation light.

The photodetection element 200 receives reflected light with respect to the irradiation light, and measures a round-trip time from a light emission timing indicated by the light emission control signal CLKp to a timing at which the reflected light is received. The photodetection element 200 calculates the distance to the object from the round-trip time, and generates and outputs distance data indicating the distance.

### Configuration Example of Photodetection Element

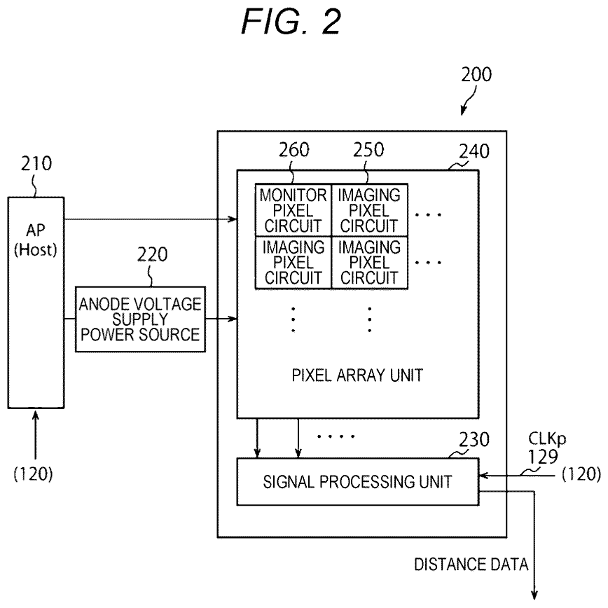

FIG. 2 is a block diagram illustrating a configuration example of the photodetection element 200 according to the first embodiment of the present technology. The photodetection element 200 includes a control circuit 210, an anode potential supply power source 220, a signal processing unit 230, and a pixel array unit (sensor) 240. Note that the control circuit 210 can also be configured in the control unit 120 (see FIG. 1).

The control circuit 210 is, for example, an application processor (AP), and can control the potential of each pixel circuit in the pixel array unit 240. Details of the control circuit 210 will be described later.

The anode potential supply power source 220 supplies the anode potential to the pixel circuit in the pixel array unit 240 under the control of the control circuit 210. Note that the anode potential supply power source 220 according to the present embodiment corresponds to a power source circuit.

The signal processing unit 230 measures the round-trip time for each pixel circuit on the basis of the signal from the pixel circuit and the light emission control signal CLKp from the control unit 120, and calculates the distance. The signal processing unit 230 generates distance data indicating the distance for each of pixel circuit and outputs the distance data to the outside.

In the pixel array unit 240, an imaging pixel circuit 250 and a monitor pixel circuit 260 are arranged in a two-dimensional lattice pattern. Details of the pixel array unit 240 will also be described later. Furthermore, the total number of the monitor pixel circuits 260 and the pixel array units 240 is N (N is an integer of 2 or more). Furthermore, at least one of the N pixel circuits is the monitor pixel circuit 260, and the rest are the imaging pixel circuits 250. Hereinafter, a set of pixel circuits arranged in a horizontal direction may be referred to as “row”, and a set of pixel circuits arranged in a direction perpendicular to the row may be referred to as “column”. Note that the imaging pixel circuit 250 and the monitor pixel circuit 260 according to the present embodiment correspond to pixel circuits. Furthermore, in this case, the distance data is generated for each imaging pixel circuit 250.

### Configuration Example of Pixel Array Unit

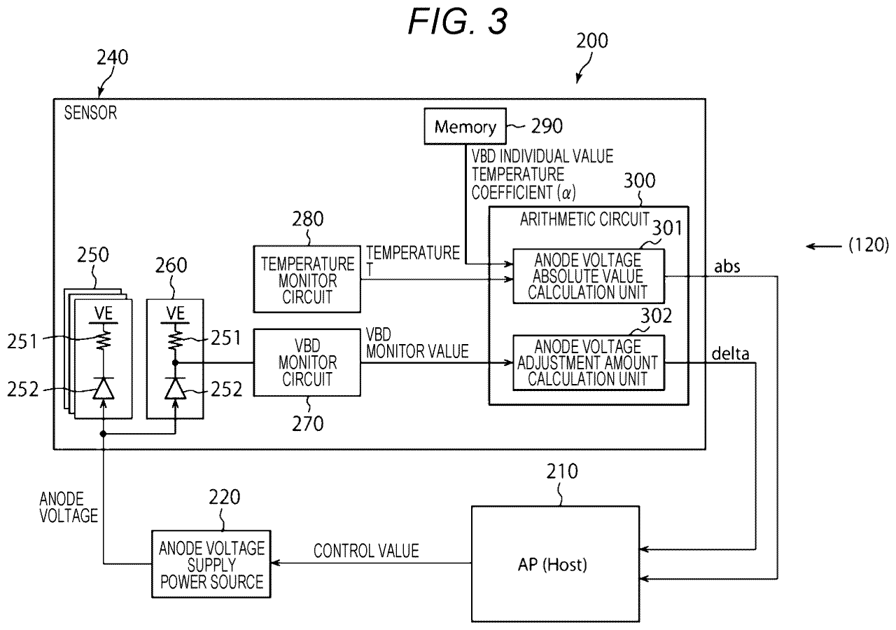

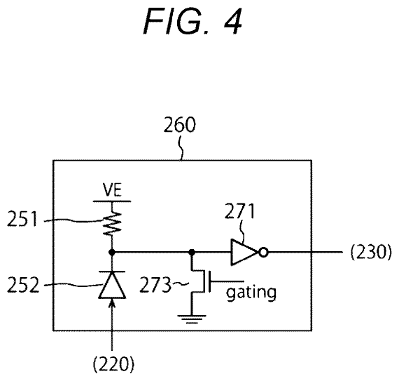

FIG. 3 is a diagram illustrating a configuration example of a pixel array unit and a control circuit according to the present embodiment. In the following description, in order to simplify the description, a part of the configurations in the signal processing unit 230 and the imaging pixel circuit 250 may be omitted. Note that details of the imaging pixel circuit 250 will be described later with reference to FIG. 4.

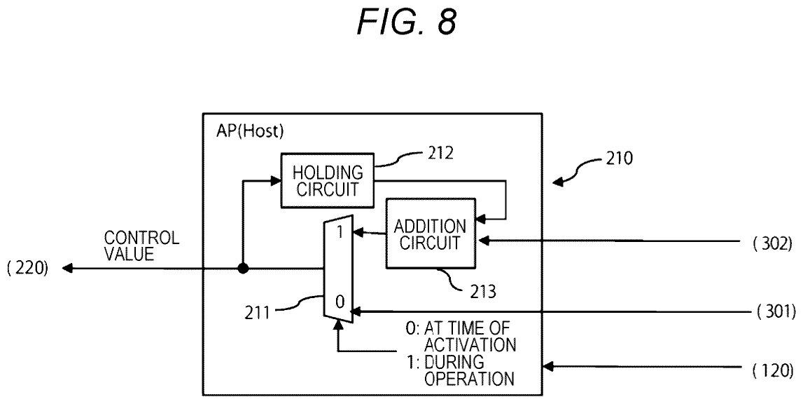

As illustrated in FIG. 3, the pixel array unit (sensor) 240 includes a plurality of imaging pixel circuits 250, a monitor pixel circuit 260, a VBD monitor circuit 270, a temperature monitor circuit 280, a storage unit (memory) 290, and an arithmetic circuit 300. Furthermore, the arithmetic circuit 300 includes an anode potential absolute value calculation unit 301 and an anode potential adjustment amount calculation unit 302. Note that details of the control circuit 210 will be described later with reference to FIG. 8. Furthermore, in the present embodiment, the control circuit 210 and the arithmetic circuit 300 are configured separately, but the present invention is not limited thereto. For example, the control circuit 210 and the arithmetic circuit 300 may be integrally configured as one element. In this case, the arithmetic circuit 300 may be configured without the control circuit 210. Alternatively, the control circuit 210 may be configured without the arithmetic circuit 300. Furthermore, the control circuit 210 and the arithmetic circuit 300 configured as one element may be configured without the pixel array unit 240. Alternatively, the control circuit 210 configured as one element and the arithmetic circuit 300 may be configured outside the pixel array unit 240.

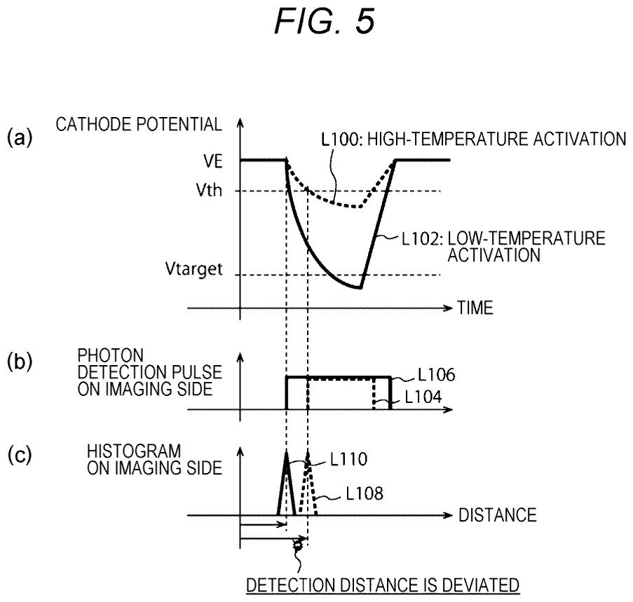

Here, the imaging pixel circuit 250 and an example of temperature characteristics of the imaging pixel circuit 250 will be described with reference to FIGS. 4 and 5. FIG. 4 is a diagram illustrating a circuit configuration example of the imaging pixel circuit 250. As illustrated in FIG. 4, the imaging pixel circuit 250 includes a resistor 251, a photodiode 252, an inverter 271, and a transistor 273.

FIG. 5 is a diagram illustrating temperature characteristics when a constant anode potential Vacon is applied to the anode of the photodiode 252. (a) of the drawing is a diagram illustrating a cathode potential Vc in a case where the constant anode potential Vacon is applied to the anode of the photodiode 252. The vertical axis represents the cathode potential Vc, and the horizontal axis represents time.

(b) of the drawing is a diagram illustrating an output signal of the inverter 271. The vertical axis represents a signal level, and the horizontal axis represents time. (c) of the drawing is a diagram illustrating an example of a histogram of rise times of pulses generated by the signal processing unit 230. The vertical axis represents frequency, and the horizontal axis represents time. In the present embodiment, the object to be measured is irradiated with the measurement light a plurality of times. Therefore, rise times of the plurality of pulses are generated by the signal processing unit 230.

As illustrated in FIG. 4, one end of the resistor 251 is connected to the cathode of the photodiode 252, and the other end is connected to the terminal of a potential VE. When the reflected light is incident, the photodiode 252 photoelectrically converts the incident light and outputs a photocurrent. For example, a SPAD is used as the photodiode 252. Furthermore, the anode potential supplied from the anode potential supply power source 220 to the photodiode 252 is controlled by the control circuit 210.

As illustrated in (a) of FIG. 5, at the time of incidence of the reflected light, the photocurrent from the photodiode 252 flows through the resistor 251, and the cathode potential Vc drops from the potential VE according to the current value. When the constant anode potential Vacon is applied to the anode of the photodiode 252, the drop voltage of the cathode potential Vc becomes smaller as indicated by a line L100 in the cathode potential Vc at the time of a high-temperature activation of the photodiode 252. On the other hand, when the constant anode potential Vacon is applied to the anode of the photodiode 252, the drop voltage of the cathode potential Vc becomes larger as indicated by a line L102 in the cathode potential Vc at the time of low-temperature activation of the photodiode 252.

In the present embodiment, the minimum value of the cathode potential Vc is referred to as a bottom potential Vbtm. A voltage of a difference between the constant anode potential Vacon of the photodiode 252 and the bottom potential Vbtm is referred to as a breakdown voltage VBD.

The inverter 271 inverts a signal of the cathode potential Vc of the photodiode 252 and outputs the same as a pulse signal OUT to a signal processing circuit 230. As illustrated in (b) of the drawing, the inverter 271 outputs pulse signals L104 and L106 at a low level in a case where the cathode potential Vc is higher than a predetermined threshold Vth, and outputs pulse signals L104 and L106 at a high level in a case where the cathode potential Vc is equal to or lower than the threshold. The pulse signal L104 corresponds to high-temperature activation, and the pulse signal L106 corresponds to low-temperature activation.

As illustrated in (c) of the drawing, the signal processing unit 230 can detect a timing based on the statistical value of rising of the pulse signal OUT as the light receiving timing on the basis of the rising histograms of the pulse signals L104 and L106. A histogram signal L108 corresponds to the high-temperature activation, and the histogram signal L110 corresponds to the low-temperature activation.

In a case where the photodiode 252 is a SPAD, the SPAD is used in Geiger mode in which a reverse bias is applied to a voltage equal to or higher than a certain voltage. Then, when light is detected, an anode-cathode voltage VEX decreases to a quench voltage (voltage at the time of generation of the bottom potential Vbtm) due to impact ionization, and the photodiode 252 transitions from a high impedance state to a low impedance state. The photodetection element 200 can create ToF data by detecting a change in the cathode potential at that time with a threshold Vth, for example. When the anode-cathode voltage decreases to the quench voltage, the photodiode 252 becomes high impedance again, and shifts to Geiger mode again by pull-up due to the high impedance.

As can be seen from these, in a case where the temperature at the time of activation is different, the drop characteristic of the cathode potential Vc fluctuates, and the quench voltage fluctuates. Therefore, the detection distance varies. Therefore, in the present embodiment, the temperature is measured by the temperature monitor circuit 280, and the anode potential of the photodiode 252 is controlled so that the bottom potential Vbtm of the photodiode 252 at the time of activation becomes close to a target potential Vtarget without depending on the temperature.

As illustrated in FIG. 3, the monitor pixel circuit 260 includes a resistor 251 and a photodiode 252 similarly to the imaging pixel circuit 250. Similarly to the imaging pixel circuit 250, at the time of incidence of the reflected light, the photocurrent from the photodiode 252 flows through the resistor 251, and the cathode potential Vc drops according to the current value.

The VBD monitor circuit 270 monitors a signal of the cathode potential Vc of the photodiode 252 in the monitor pixel circuit 260. More specifically, the VBD monitor circuit 270 samples the cathode potential Vc of the region including the lowermost portion of the cathode potential Vc, that is, the bottom potential Vbtm. The VBD monitor circuit 270 outputs the sampled bottom potential Vbtm to the anode potential adjustment amount calculation unit 302 of the arithmetic circuit 300. Note that details of the VBD monitor circuit 270 will be described later.

The temperature monitor circuit 280 monitors the temperature of the photodiode 252 in the monitor pixel circuit 260. The temperature monitor circuit 280 is, for example, a temperature sensor arranged in the pixel array unit 240. The temperature monitor circuit 280 can monitor the temperature of the photodiode 252 in consideration of, for example, a temperature gradient and the like in the pixel array unit 240. The temperature monitor circuit 280 outputs the measured temperature value to an anode potential absolute value calculation unit 302 of the arithmetic circuit 300. Note that the temperature monitor circuit 280 according to the present embodiment corresponds to a temperature detection circuit.

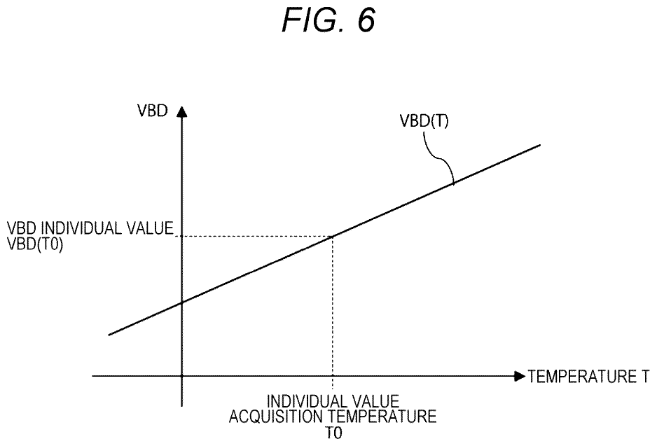

The storage unit (Memory) 290 stores an individual value temperature coefficient & in the photodiode 252. FIG. 6 is a diagram illustrating an example of temperature characteristics of the cathode potential Vc. The vertical axis represents the breakdown voltage VBD of the photodiode 252, and the horizontal axis represents temperature. A temperature characteristic line VBD(T) of the breakdown voltage has, for example, a linear characteristic with respect to temperature. Note that, in the present embodiment, the temperature characteristic line VBD(T) is described as linear, but the present invention is not limited thereto. For example, a non-linear function may be used.

The slope of the temperature characteristic line VBD(T) is defined as an individual value temperature coefficient α. For example, the individual value temperature coefficient α can be measured by test measurement at the time of shipment of sensors. For example, an individual value acquisition temperature T0 at the time of shipment and the value of a temperature characteristic line VBD(T0) at that time are stored in the storage unit 290 as a VBD individual value VBD(T0). Since the individual value temperature coefficient α, the individual value acquisition temperature T0, and the VBD individual value VBD(T0) are stored, the temperature characteristic line VBD(T) at each temperature T can be obtained by linear calculation. Note that, in the case of non-linearity, the temperature characteristic line VBD(T) may be stored in the storage unit 290 as a temperature table.

The anode potential absolute value calculation unit 301 of the arithmetic circuit 300 calculates the anode potential of the photodiode 252 using the monitored temperature value T of the temperature monitor circuit 280, the individual value temperature coefficient a, the individual value acquisition temperatures T0 and VBD, and the individual value VBD(T0). That is, for example, as shown in Expression (1), the breakdown voltage VBD(T) at the temperature T is VBD(T0)+α×(T−T0). The anode potential of the photodiode 252 when the bottom potential Vbtm at the breakdown voltage VBD(T0) becomes the target potential Vtarget is set to (VE−Vtarget)−VBD(T0)+c. c is any constant including 0. Therefore, an anode potential abs having the bottom potential Vbtm at the time of the breakdown voltage VBD(T) of the cathode potential at the temperature T as the target potential Vtarget is, for example, Expression (2).

That is, the anode potential absolute value calculation unit 301 calculates the anode potential abs of the photodiode 252 according to, for example, Expressions (1) and (2) so that the bottom potential Vbtm of the photodiode 252 at the time of activation becomes close to the target potential Vtarget.

[Math. 1]

VBD(T)=VBD(T0)+α×(T−T0) (1)

[Math. 2]

abs=(VE−Vtarget)−VBD(T)+C (2)

As illustrated in FIG. 6, the breakdown voltage VBD(T) increases as the temperature increases. Therefore, the anode potential abs decreases as the temperature increases.

On the other hand, the second and subsequent anode potentials are calculated by the anode potential adjustment amount calculation unit 302. The anode potential adjustment amount calculation unit 302 calculates an adjustment value delta of the anode potential according to Expression (3) using the bottom potential Vbtm monitored by the VBD monitor circuit 270.

[Math. 3]

delta=(Vtarget−Vbtm) (3)

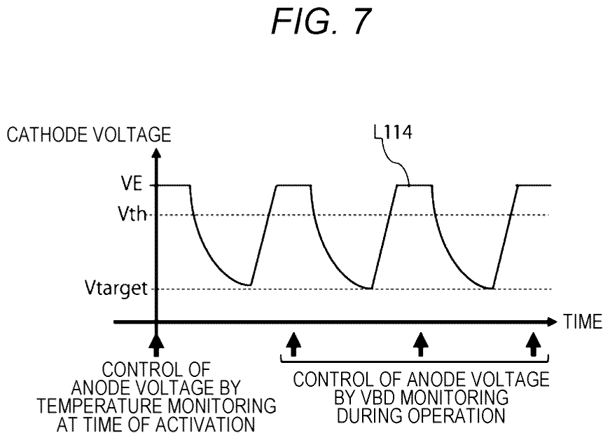

FIG. 7 is a diagram illustrating a control example of the anode potential of the photodiode 252 of the control circuit 210. In FIG. 7, as in (a) of FIG. 5, the vertical axis represents the cathode potential Vc, and the horizontal axis represents time. Here, the line L114 indicates the cathode potential Vc.

The control circuit 210 has a first mode of controlling the anode potential according to the temperature T and a second mode of supplying a lower potential to the anode of the photodiode 252 as the bottom potential Vbtm when the photocurrent flows through the resistor 251 (see FIG. 3) is higher.

That is, in the first mode, as indicated by the line L114 in FIG. 7, at the time of activation, the control circuit 210 controls the anode potential supply power source 220 so as to have the anode potential abs (see Expression (2)) of the photodiode 252 using the temperature T of the temperature monitor circuit 280 and the individual value temperature coefficient α. Therefore, the bottom potential Vbtm of the cathode potential Vc of the photodiode 252 becomes close to the target potential Vtarget.

On the other hand, in the second mode, during the operation, the control circuit 210 adds the adjustment value delta (see Expression (3)) to the previous bottom potential Vbtm using the bottom potential Vbtm of the VBD monitor circuit 270. Therefore, the bottom potential Vbtm during the second and subsequent operations asymptotically approaches substantially the same value as the target potential Vtarget. As described above, in the second mode, the control circuit 210 controls the anode potential supply power source 220 by feedback control.

In this manner, the control circuit 210 controls the anode potential in the first mode at the time of activation. The time of activation is, for example, a case where the supply of the anode potential is started again after the supplying of the anode potential of the photodiode 252 is stopped. On the other hand, the control circuit 210 controls the anode potential in the second mode during the operation. The in-operation is a state in which the anode potential of the photodiode 252 is continuously supplied. That is, in the present embodiment, the anode potential is controlled in the second mode after the anode potential is controlled in the first mode.

FIG. 8 is a circuit diagram illustrating a configuration example of the control circuit 210. As illustrated in FIG. 8, the control circuit 210 includes a selection circuit 211, a holding circuit 212, and an addition circuit 213.

The selection circuit 211 is, for example, a multiplexer, and the anode potential absolute value calculation unit 301 is connected to the input terminal on the 0 side, and the output terminal of the addition circuit 213 is connected to the input terminal on the 1 side. Furthermore, the output terminal of the selection circuit 211 is connected to the anode potential supply power source 220 and one end of the holding circuit 212. The selection circuit 211 selects and outputs an input signal of the input terminal on the 0 side or the input terminal on the 1 side according to a control signal of the control unit 120, for example.

The holding circuit 212 is, for example, a memory, and the other end of the holding circuit 212 is connected to one input terminal of the addition circuit 213. The holding circuit 212 holds the output value of the selection circuit 211 while updating the output value. The anode potential adjustment amount calculation unit 302 is connected to the other input terminal of the addition circuit 213.

### Operation at Activation

The selection circuit 211 outputs the anode potential abs (see Expression (2)) of the photodiode 252, which is an input of the anode potential absolute value calculation unit 301 on the 0 side, to the anode potential supply power source 220 at the time of activation of the photodetection element 200. Furthermore, the holding circuit 212 holds the anode potential abs at the time of activation. Therefore, the anode potential supply power source 220 supplies the anode potential abs (see Expression (2)) to the anode of the photodiode 252 in the imaging pixel circuit 250 and the monitor pixel circuit 260 at the time of activation.

### Operation at Operation

The addition circuit 213 adds the input value from the holding circuit 212 and the adjustment value delta (see Expression (3)), which is an input from the anode potential adjustment amount calculation unit 302, and outputs the result to the selection circuit 211. That is, the addition circuit 213 outputs the current control value obtained by adding the previous anode potential control value and the adjustment value delta.

The selection circuit 211 outputs the current control value output from the addition circuit 213 on the 1 side to the anode potential supply power source 220 during the operation of the photodetection element 200. Therefore, the bottom potential Vbtm asymptotically approaches substantially the same value as the target potential Vtarget.

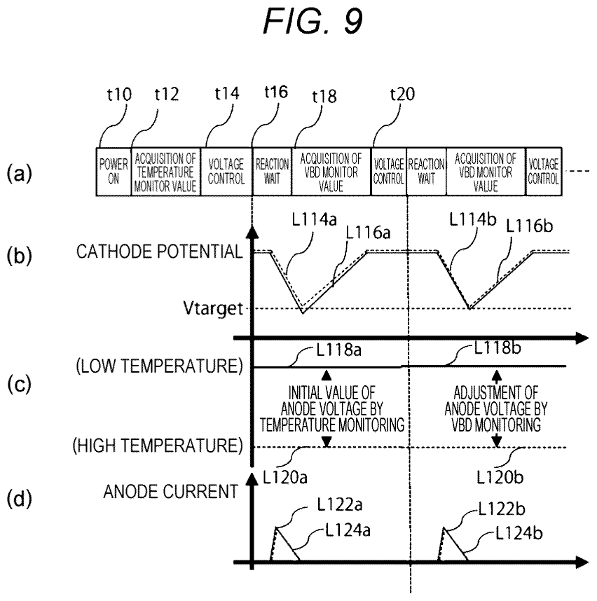

FIG. 9 is a diagram illustrating a control operation example of the photodetection element 200. (a) of the drawing is a diagram schematically illustrating a control state. The horizontal axis represents time.
(b) of the drawing illustrates the cathode potential Vc of the photodiode 252. The vertical axis represents the cathode potential Vc, and the horizontal axis represents time. Here, a line L114a indicates the cathode potential Vc at the time of low-temperature activation, and a line L116a indicates the cathode potential Vc at the time of high-temperature activation. Furthermore, a line L114b indicates the cathode potential Vc during the operation following the low-temperature activation, and a line L116b indicates the cathode potential Vc during the operation following the high-temperature activation.
(c) of the drawing illustrates the anode potential of the photodiode 252. The vertical axis represents the anode potential, and the horizontal axis represents time. Here, a line L118a indicates the anode potential at the time of low-temperature activation, and a line L120a indicates the anode potential at the time of high-temperature activation. Furthermore, a line L118b indicates the anode potential during the operation following the low-temperature activation, and a line L120b indicates the anode potential during the operation following the high-temperature activation.
(d) of the drawing illustrates an anode current of the photodiode 252. The vertical axis represents the anode current, and the horizontal axis represents time. Here, a line L122a indicates the anode current at the time of low-temperature activation, and a line L124a indicates the anode current at the time of high-temperature activation. Furthermore, a line L122b indicates the anode current during the operation following the low-temperature activation, and a line L124b indicates the anode current during the operation following the high-temperature activation.

The operation state of (a) of the drawing will be described. First, the photodetection element 200 starts driving according to the control of the control unit 120 (FIG. 1). At this time, the anode potential supply power source 220 also starts driving (timing t10). Next, the temperature monitor circuit 280 acquires the temperature monitor value according to the synchronization timing of the control unit 120, and the anode potential absolute value calculation unit 301 calculates the anode potential abs (see Expression (2)) (timing t12). Subsequently, the control circuit 210 supplies the anode potential abs to the anode potential supply power source 220, and the anode potential supply power source 220 controls the potential of the anode of the photodiode 252 in the imaging pixel circuit 250 and the monitor pixel circuit 260 to the anode potential abs (timing t14).

Next, in synchronization with the light emission of the light emitting unit 110, the generation of the photocurrent of the photodiode 252 is waited (timing t16), and the cathode potential Vc after a predetermined time when the cathode potential Vc exceeds a threshold th (see FIG. 5) is acquired as the bottom potential Vbtm by the VBD monitor circuit 270 (timing t18). Subsequently, the control circuit 210 supplies a control value obtained by adding the adjustment value delta (see Expression (3)) to the bottom potential Vbtm to the anode potential supply power source 220, and the anode potential supply power source 220 controls the potential of the anode of the photodiode 252 in the imaging pixel circuit 250 and the monitor pixel circuit 260 to the control value (timing t20). Thereafter, timings t16 to t20 are repeated until the end of imaging.

As illustrated in (c) of the drawing, by the voltage control at timing t14, the anode potential is controlled to a higher anode potential L118a at the time of low-temperature activation, and is controlled to a lower anode potential L120a at the time of high-temperature activation. Therefore, as illustrated in (b) of the drawing, in the cathode potential lines L114a and L116a, the vicinity of the target potential Vtarget becomes the bottom potential Vbtm in both the case of low-temperature activation and the case of high-temperature activation. Furthermore, as illustrated in (d) of the drawing, the anode currents L122a and L124a at this time have the same values in both the case of low-temperature activation and the case of high-temperature activation, and an error in distance measurement is suppressed.

Similarly, during operation, as illustrated in (c) of the drawing, by voltage control at timing t20, the anode potential is controlled to a higher anode potential L118b at the time of low-temperature activation, and is controlled to a lower anode potential L120b at the time of low-temperature activation. Therefore, as illustrated in (b) of the drawing, the bottom potential Vbtm of the cathode potential lines L114b and L116b becomes a value near the target potential Vtarget at the time of low-temperature activation and during the operation following the high-temperature activation. Furthermore, as illustrated in (d) of the drawing, the anode currents L122b and L124b at this time also have the same value at the time of low-temperature activation and during the operation following the high-temperature activation, and an error in distance measurement is suppressed.

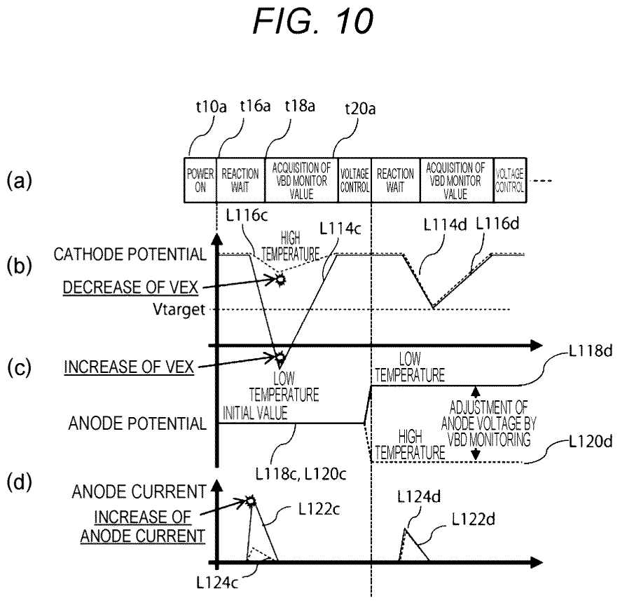

FIG. 10 is a diagram illustrating a control operation example of the photodetection element 200 in a case where the temperature monitor value is not used as a comparative example. (a) to (d) of the drawing are similar to FIG. 8. (a) of the drawing is a diagram schematically illustrating an operation state in a case where the temperature monitor value is used. The horizontal axis represents time.
(b) of the drawing illustrates the cathode potential Vc of the photodiode 252. The vertical axis represents the cathode potential Vc, and the horizontal axis represents time. Here, a line L114c indicates the cathode potential Vc at the time of low-temperature activation, and a line L116c indicates the cathode potential Vc at the time of high-temperature activation. Furthermore, a line L114d indicates the cathode potential Vc during the operation following the low-temperature activation, and a line L116d indicates the cathode potential Vc during the operation following the high-temperature activation.
(c) of the drawing illustrates the anode potential of the photodiode 252. The vertical axis represents the anode potential, and the horizontal axis represents time. Here, a line L118c indicates the anode potential at the time of low-temperature activation, and a line L120c indicates the anode potential at the time of high-temperature activation. Furthermore, a line L118d indicates the anode potential during the operation following the low-temperature activation, and a line L120d indicates the anode potential during the operation following the high-temperature activation.
(d) of the drawing illustrates an anode current of the photodiode 252. The vertical axis represents the anode current, and the horizontal axis represents time. Here, a line L122c indicates the anode current at the time of low-temperature activation, and a line L124c indicates the anode current at the time of high-temperature activation. Furthermore, a line L122d indicates the anode current during the operation following the low-temperature activation, and a line L124d indicates the anode current during the operation following the high-temperature activation.

The operation state of (a) of the drawing will be described. First, the photodetection element 200 starts driving according to the control of the control unit 120 (FIG. 1). At this time, the anode potential supply power source 220 also starts driving, and the anode potential supply power source 220 controls the potentials of the anodes of the photodiodes 252 in the imaging pixel circuit 250 and the monitor pixel circuit 260 to a predetermined fixed potential (timing t10a).

Next, in synchronization with the light emission of the light emitting unit 110, the generation of the photocurrent of the photodiode 252 is waited (timing t16a), and the cathode potential Vc after a predetermined time when the cathode potential Vc exceeds a threshold th (see FIG. 5) is acquired as the bottom potential Vbtm by the VBD monitor circuit 270 (timing t18a). The control circuit 210 supplies a control value obtained by adding the adjustment value delta (see Expression (3)) to the bottom potential Vbtm to the anode potential supply power source 220, and the anode potential supply power source 220 controls the potential of the anode of the photodiode 252 in the imaging pixel circuit 250 and the monitor pixel circuit 260 to the control value (step S20a). Thereafter, timings t16a to t20a are repeated until the end of imaging.

As illustrated in (c) of the drawing, by the voltage control at timing t10a, the anode potentials are controlled to the same anode potentials L118c and L120c both cases at the time of low-temperature activation and at the time of high-temperature activation. Therefore, as illustrated in (b) of the drawing, the cathode potential line L114c may exceed the target potential Vtarge at the time of low-temperature activation. Therefore, the voltage VEX between the anode and the cathode of the photodiode 252 increases more than the target voltage.

On the other hand, as illustrated in (b) of the drawing, at the time of high-temperature activation, the cathode potential line L116c may be in a state of not reaching the target potential Vtarge. Therefore, the voltage VEX between the anode and the cathode of the photodiode 252 decreases more than the target voltage. Therefore, as illustrated in FIG. 5, an error occurs in distance measurement.

Furthermore, as illustrated in (d) of the drawing, the anode currents L122c and L124c at this time vary between the case of low-temperature activation and the case of high-temperature activation.

Similarly, during operation, as illustrated in (c) of the drawing, by voltage control at timing t20a, the anode potential is controlled to a higher anode potential L118d at the time of low-temperature activation, and is controlled to a lower anode potential L120d at the time of low-temperature activation. Therefore, as illustrated in (b) of the drawing, the vicinity of the target potential Vtarget of the cathode potential lines L114d and L116d becomes the bottom potential Vbtm also at the time of low-temperature activation and during the operation following the high-temperature activation. Furthermore, as illustrated in (d) of the drawing, the anode currents L122d and L124d at this time also have the same value at the time of low-temperature activation and during the operation following the high-temperature activation, and an error in distance measurement is suppressed. As described above, when the potentials of the anodes of the photodiodes 252 in the imaging pixel circuit 250 and the monitor pixel circuit 260 are controlled at a predetermined fixed potential at the time of activation, the measurement error at the time of activation increases due to the influence of the temperature characteristics of the photodiodes 252.

On the other hand, in the control circuit 210 according to the present application, as described above, the temperature monitor circuit 280 acquires the temperature monitor value, and the anode potential absolute value calculation unit 301 calculates the anode potential abs (see Expression (2)). Then, since the control circuit 210 controls the potentials of the anodes of the photodiodes 252 in the imaging pixel circuit 250 and the monitor pixel circuit 260 to the anode potential abs, the influence of the temperature characteristics of the photodiode 252 can be suppressed, and the measurement error at the time of activation is suppressed.

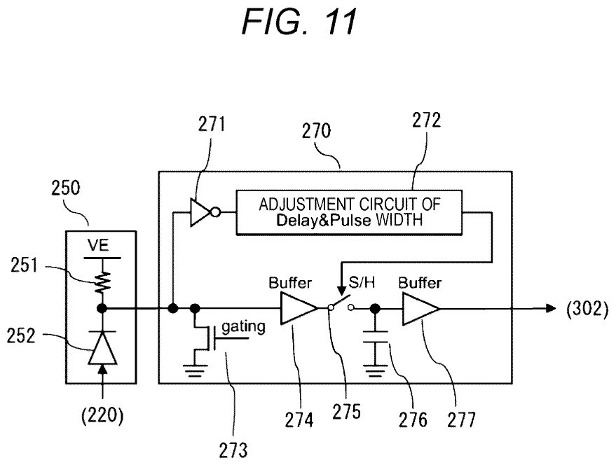

Here, the configuration of the BD monitor circuit 270 will be described in more detail with reference to FIG. 11. FIG. 11 is a circuit diagram illustrating a configuration example of the monitor pixel circuit 260 and the VBD monitor circuit 270. The monitor pixel circuit 260 includes the resistor 251 and the photodiode 252 as described above. Furthermore, the VBD monitor circuit 270 includes an inverter 271, an adjustment circuit 272, a transistor 273, a plurality of buffers 274 and 277, a switching element 275, and a capacitance 276.

The inverter 271 of the VBD monitor circuit 270 inverts the signal of the cathode potential Vc of the photodiode 252 and outputs the inverted signal to the adjustment circuit 272 as the pulse signal OUT. The inverter 271 outputs a low-level pulse signal OUT in a case where the cathode potential Vc is higher than a predetermined value, and outputs a high-level pulse signal OUT in a case where the cathode potential is equal to or lower than the predetermined value. The adjustment circuit 272 adjusts the delay time and the high-level width of the high-level pulse signal OUT output from the inverter 271.

As the transistor 273, for example, an N type metal oxide semiconductor (MOS) transistor is used. To the gate of the transistor 273, a gate signal GAT at a predetermined potential is applied, the source thereof is connected to a back gate and a ground terminal, and the drain thereof is connected to the cathode of the photodiode 252, an input terminal of the inverter 271, and an input terminal of the buffer 274. For example, a low level is set to the gate signal in a row reading period.

An output terminal of the buffer 274 is connected to one end of the switching element 275. Furthermore, the other end of the switching element 275 is connected to an input terminal of the buffer 277 and one end of the capacitance 276. The switching element 275 is, for example, an N-type metal oxide semiconductor (MOS) transistor, and enters a connected state when an output signal of the adjustment circuit 272 is at a high level, and enters a non-connected state when the output signal is at a low level.

The other end of the electrostatic capacitance 276 is connected to the ground potential. The capacitance 276 samples the cathode potential Vc when the switching element 275 is in the connected state. As illustrated in FIG. 8, since the bottom potential Vbtm according to the present embodiment is controlled to the target potential Vtarget, the adjustment circuit 272 can monitor the bottom potential Vbtm of the cathode potential Vc by adjusting the delay time and the high-level width of the high-level pulse signal OUT applied to the switching element 275. That is, the capacitance 276 samples the bottom potential Vbtm.

An output terminal of the buffer 277 is connected to the anode potential adjustment amount calculation unit 302 (see FIG. 3) of the arithmetic circuit 300. The buffer 277 outputs the sampled value of the bottom potential Vbtm to the anode potential adjustment amount calculation unit 302.

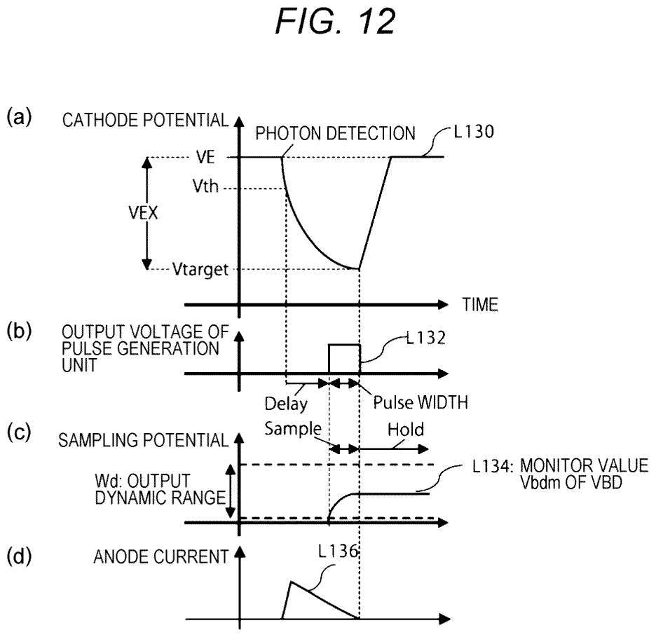

FIG. 12 is a diagram illustrating an example of operation characteristics of the VBD monitor circuit 270. (a) of the drawing is a diagram illustrating the cathode potential Vc of the photodiode 252. The vertical axis represents the cathode potential Vc, and the horizontal axis represents time. A line L130 indicates a temporal change of the cathode potential Vc. (b) of the drawing is a diagram illustrating an output signal of the adjustment circuit 272. The vertical axis represents a signal level, and the horizontal axis represents time. (c) of the drawing is a diagram illustrating a sampling potential of the capacitance 276. The vertical axis represents the bottom potential Vbtm, and the horizontal axis represents time. Furthermore, a range of the potential of the capacitance 276 that can be sampled is indicated as an output dynamic range Wd. A line L134 indicates a temporal change of the bottom potential Vbtm. (d) of the drawing is a diagram illustrating an anode current of the photodiode 252. The vertical axis represents the anode current, and the horizontal axis represents time. A line L136 indicates a temporal change of the anode current.

As indicated by the line L130 in (a) of the drawing, in a case where the control is performed by the control circuit 210, the bottom potential Vbtm of the cathode potential Vc is close to the target potential Vtarget. The voltage VEX between the cathode and the anode in the photodiode 252 at this time is a target value.

As indicated by a line L132 in (b) of the drawing, the inverter 271 outputs a low-level pulse signal OUT in a case where the cathode potential Vc is higher than a predetermined threshold. Then, the adjustment circuit 272 delays the pulse signal OUT by a predetermined time delay and shapes the pulse signal OUT to a predetermined pulse width. The time delay and the pulse width are set at the position of the bottom potential Vbtm of the cathode potential Vc. Therefore, as indicated by the line L 134 in (c) of the drawing, the capacitance 276 samples the bottom potential Vbtm of the cathode potential Vc, and outputs the bottom potential Vbtm. Furthermore, as indicated by the line L136 in (d) of the drawing, the anode current also has a peak at a target time with respect to the threshold Vth.

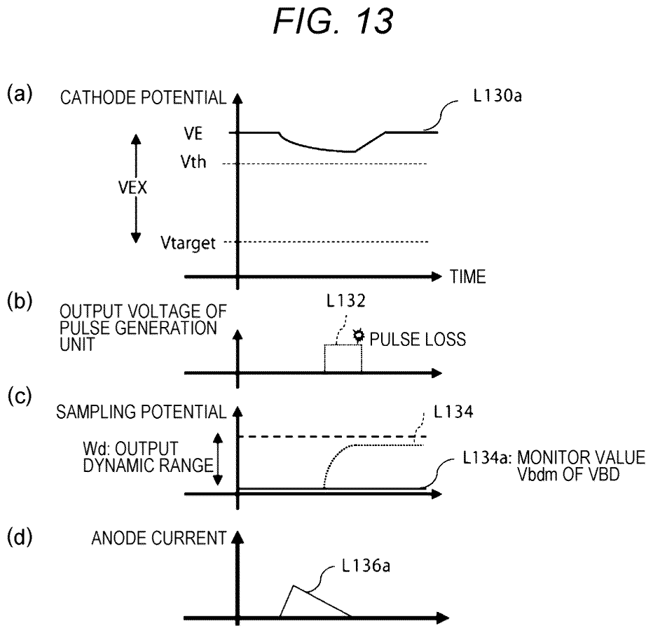

FIG. 13 is a diagram illustrating an example of operation characteristics of the VBD monitor circuit 270 in a case where the temperature monitor value is not used at a high temperature. (a) to (d) of the drawing are diagrams equivalent to FIG. 12. (a) of the drawing is a diagram illustrating the cathode potential Vc of the photodiode 252. A line L130a indicates a temporal change of the cathode potential Vc at the time of activation in a case where the temperature monitor value is not used as a temperature at the time of activation. (b) of the drawing is a diagram illustrating an output signal of the adjustment circuit 272. The vertical axis represents a signal level, and the horizontal axis represents time. (c) of the drawing is a diagram illustrating a sampling potential of the capacitance 276. The vertical axis represents the bottom potential Vbtm, and the horizontal axis represents time. A line L134a indicates a temporal change of the bottom potential Vbtm. (d) of the drawing is a diagram illustrating an anode current of the photodiode 252. A line L136a indicates a temporal change of the anode current.

As indicated by the line L130a in (a) of the drawing, in a case where the control circuit 210 does not perform control using the temperature monitor value, the bottom potential Vbtm of the cathode potential Vc becomes a high potential and does not exceed a threshold potential Vth in some cases. In this case, as illustrated in (b) of the drawing, since the inverter 271 always outputs the low-level pulse signal OUT, the adjustment circuit 272 cannot generate a high-level signal. Therefore, the capacitance 276 cannot sample the bottom potential Vbtm of the cathode potential Vc and maintains the initial value. Furthermore, the anode current also further decreases as indicated by the line L136a in (d) of the drawing. As described above, in a case where the temperature monitor value is not used at a high temperature, the bottom potential Vbtm of the cathode potential Vc cannot be sampled, and control in the control circuit 210 during operation is not performed.

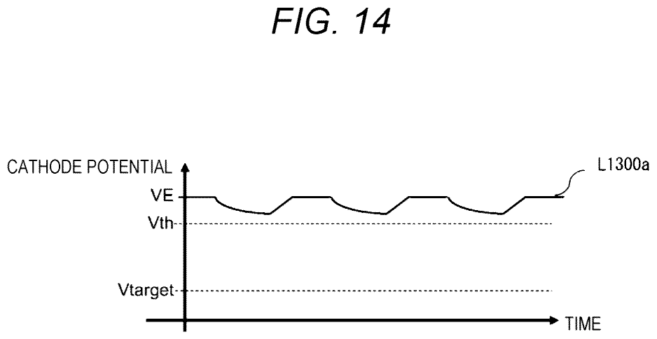

FIG. 14 is a diagram illustrating a temporal change of the cathode potential Vc in a case where the temperature monitor value is not used at a high temperature. The vertical axis represents the cathode potential Vc of the photodiode 252, and the horizontal axis represents time. A line L1300a indicates a temporal change of the cathode potential Vc at the time of activation in a case where the control circuit 210 does not perform control using the temperature monitor value. As illustrated in FIG. 13, in a case where the bottom potential Vbtm of the cathode potential Vc becomes a high potential and does not exceed the threshold potential Vth, control during operation in the control circuit 210 becomes impossible, and a state in which the cathode potential Vc does not exceed the threshold potential Vth is continued at all times. As described above, in a case where the control circuit 210 does not perform control at the time of driving using the temperature monitor value, control during operation becomes impossible, and an error in distance measurement remains increased.

On the other hand, since the control circuit 210 according to the present application controls the potential of the anodes of the photodiodes 252 in the imaging pixel circuit 250 and the monitor pixel circuit 260 to the anode potential abs (see Expression (2)) at the time of driving as described above, it is possible to suppress the influence of the temperature characteristics of the photodiode 252 of the temperature characteristic and to suppress the measurement error at the time of activation.

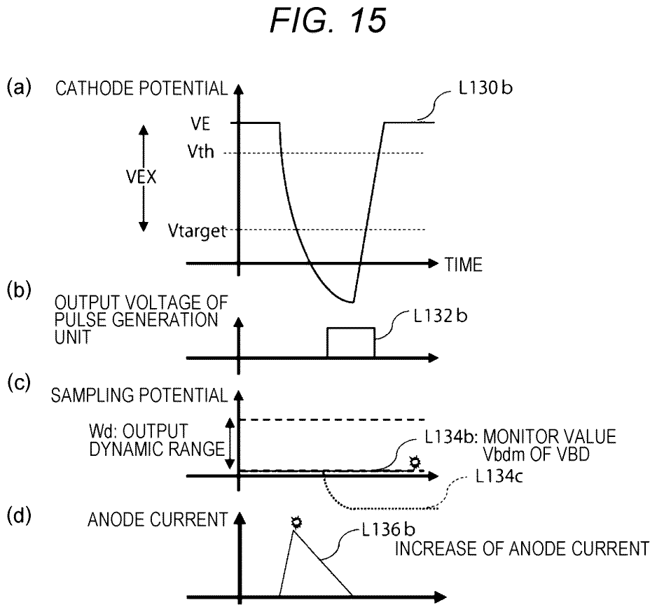

FIG. 15 is a diagram illustrating an example of operation characteristics of the VBD monitor circuit 270 in a case where the temperature monitor value is not used at a low temperature. (a) to (d) of the drawing are diagrams equivalent to FIG. 12. (a) of the drawing is a diagram illustrating the cathode potential Vc of the photodiode 252. A line L130b indicates a temporal change of the cathode potential Vc at the time of activation in a case where the temperature monitor value is not used as a temperature at the time of activation. (b) of the drawing is a diagram illustrating an output signal of the adjustment circuit 272. The vertical axis represents a signal level, and the horizontal axis represents time. A line L132b indicates a temporal change of the output signal of the adjustment circuit 272. (c) of the drawing is a diagram illustrating a sampling potential of the capacitance 276. The vertical axis represents the bottom potential Vbtm, and the horizontal axis represents time. A line L134b indicates a temporal change of the bottom potential Vbtm. (d) of the drawing is a diagram illustrating an anode current of the photodiode 252. A line L136b indicates a temporal change of the anode current.

As indicated by the line L130b in (a) of the drawing, in a case where the control is not performed by the control circuit 210, the bottom potential Vbtm of the cathode potential Vc becomes a low potential and may become smaller than the target potential Vtarget. In this case, as illustrated in (b) of the drawing, the adjustment circuit 272 generates a high-level signal. However, as illustrated in (c) of the drawing, since the bottom potential Vbtm indicated by a line L134c exceeds the potential in the range where the capacitance 276 can be sampled, the capacitance 276 cannot sample the bottom potential Vbtm L134c of the cathode potential Vc, and samples the value of L134b which is an incorrect value. Furthermore, the anode current also increases as indicated by the line L136b in (d) of the drawing.

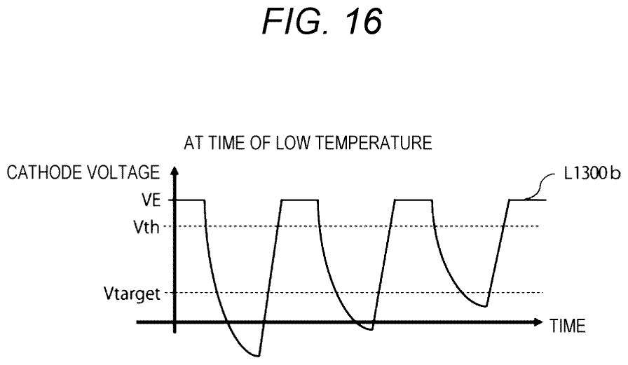

FIG. 16 is a diagram illustrating a temporal change of the cathode potential Vc in a case where the temperature monitor value is not used at a low temperature. The vertical axis represents the cathode potential Vc of the photodiode 252, and the horizontal axis represents time. A line L1300b indicates a temporal change of the cathode potential Vc at the time of activation in a case where the control circuit 210 does not perform control using the temperature monitor value. As illustrated in FIG. 15, in a case where the bottom potential Vbtm of the cathode potential Vc becomes a low potential and becomes smaller than the target potential Vtarget, the anode potential is controlled by the bottom potential Vbtm having a value sampled erroneously. Therefore, it takes time to converge to the target potential Vtarget. Therefore, current consumption increases, and a distance measurement error increases.

On the other hand, since the control circuit 210 according to the present application controls the potential of the anodes of the photodiodes 252 in the imaging pixel circuit 250 and the monitor pixel circuit 260 to the anode potential abs (see Expression (2)) at the time of driving as described above, it is possible to suppress the influence of the temperature characteristics of the photodiode 252 and to suppress the measurement error at the time of activation.

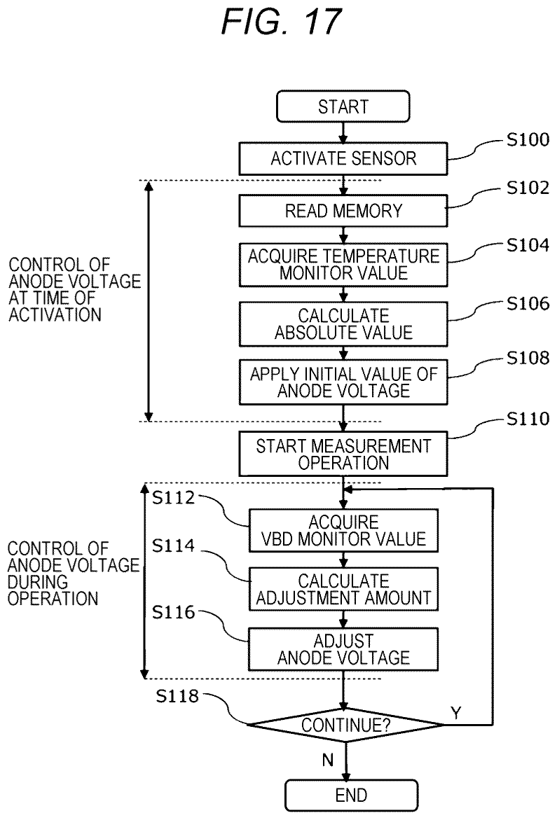

FIG. 17 is a flowchart illustrating an operation example of the photodetection element 200 according to the present embodiment. As illustrated in FIG. 17, first, the photodetection element 200 starts driving according to the control of the control unit 120 (FIG. 1) (step S100). Subsequently, the anode potential absolute value calculation unit 301 reads a coefficient a from the storage unit 290 (step S102). Subsequently, the temperature monitor circuit 280 acquires the temperature T and supplies the temperature T to the anode potential absolute value calculation unit 301 (step S104).

Next, the anode potential absolute value calculation unit 301 calculates an anode potential abs (see Expression (2)) (step S106). Subsequently, the control circuit 210 supplies the anode potential abs to the anode potential supply power source 220, and the anode potential supply power source 220 controls the potential of the anode of the photodiode 252 in the imaging pixel circuit 250 and the monitor pixel circuit 260 to the anode potential abs (step S108). Subsequently, measurement at the time of activation is started in synchronization with light emission of the light emitting unit 110 (step S110).

Next, the VBD monitor circuit 270 waits for generation of the photocurrent of the photodiode 252, and acquires the cathode potential Vc after a predetermined time when the cathode potential Vc exceeds the threshold th (see FIG. 5) as the bottom potential Vbtm (step S112). Subsequently, the anode potential adjustment amount calculation unit 302 calculates an adjustment value delta (see Expression (3)) (step S114).

Next, the control circuit 210 supplies a control value obtained by adding the adjustment value delta (see Expression (3)) to the bottom potential Vbtm to the anode potential supply power source 220. The anode potential supply power source 220 adjusts the potentials of the anodes of the photodiodes 252 in the imaging pixel circuit 250 and the monitor pixel circuit 260 to control values, and performs measurement at the time of activation in synchronization with light emission of the light emitting unit 110 (step S116). The control unit 120 determines whether or not to continue the processing (step S118), and repeats the process from step S118 when continuing (Y in step S112). On the other hand, when the process is ended (N in step S118), the control unit 120 ends the entire process.

As described above, according to the present embodiment, the control circuit 210 controls the anode potential of the photodiode 252 according to the temperature T of the photodiode 252 at the time of activation. Therefore, temperature fluctuation of the anode potential in the photodiode 252 can be suppressed, and the bottom potential Vbtm of the photodiode 252 can be controlled to a predetermined target potential Vtarget. Furthermore, the anode-cathode voltage VEX at the time of breakdown becomes constant regardless of the temperature, and a decrease in distance measurement accuracy is suppressed.

### First Modification of First Embodiment

A ranging module 100 according to a first modification of the first embodiment is different from the ranging module 100 according to the first embodiment in that an arithmetic circuit 300a also has a circuit configuration of the control circuit 210. Hereinafter, differences from the ranging module 100 according to the first embodiment will be described below.

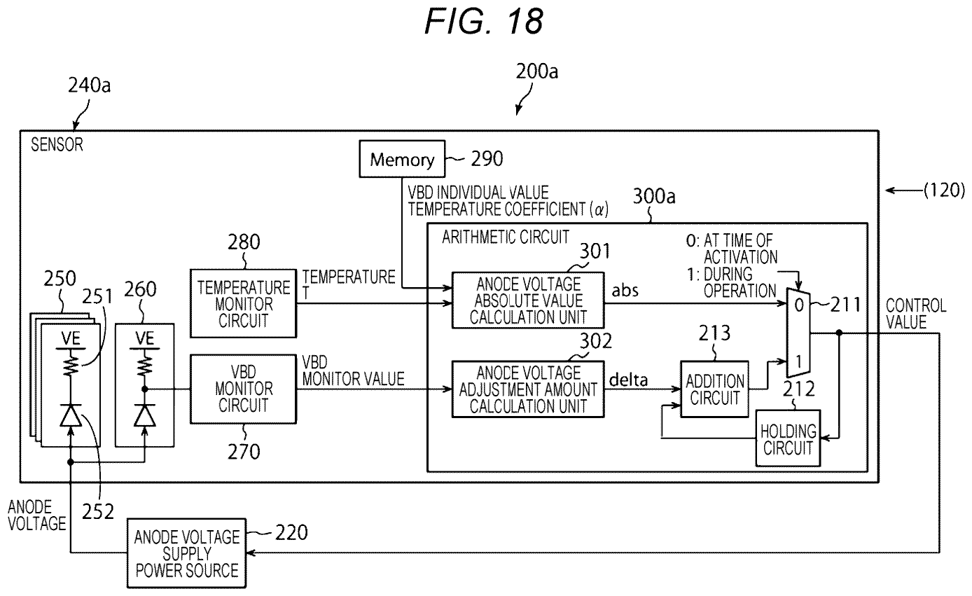

FIG. 18 is a diagram illustrating a configuration example of a pixel array unit 240a and an arithmetic circuit 300a according to the first modification of the first embodiment. In FIG. 18, description of the signal processing unit 230 is omitted. Furthermore, the imaging pixel circuit 250 illustrates a part of the circuit configuration. As illustrated in FIG. 18, the ranging module is different from the ranging module 100 according to the first embodiment in that the arithmetic circuit 300a also has a circuit configuration of the control circuit 210 (see FIG. 8). With such a configuration, by integrating the circuit configuration of the control circuit 210 and the circuit configuration of the arithmetic circuit 300a in the same element, a photodetection element 200a can be further downsized.

### Second Modification of First Embodiment

A ranging module 100 according to a second modification of the first embodiment is different from the ranging module 100 according to the first embodiment in that the arithmetic circuit 300a also has a circuit configuration of the control circuit 210, and a pixel array unit 240b and an arithmetic circuit 300b are separated. Hereinafter, differences from the ranging module 100 according to the first embodiment will be described below.

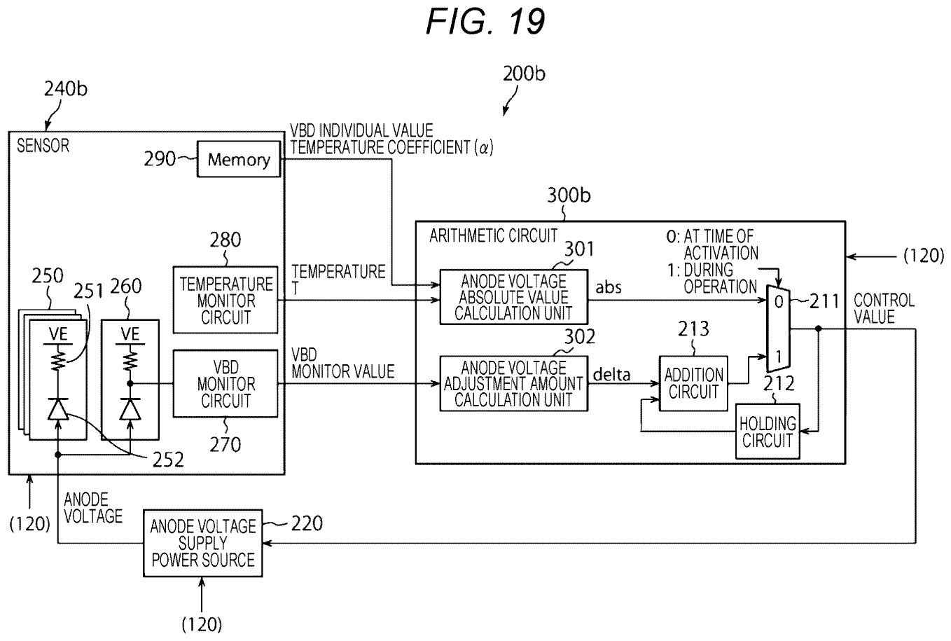

FIG. 19 is a diagram illustrating a configuration example of a pixel array unit 240b and an arithmetic circuit 300b according to the second modification of the first embodiment. In FIG. 19, description of the signal processing unit 230 is omitted. Furthermore, the imaging pixel circuit 250 illustrates a part of the circuit configuration. As illustrated in FIG. 19, it is different from the ranging module 100 according to the first embodiment in that the arithmetic circuit 300b also has a circuit configuration of the control circuit 210, and the pixel array unit 240b and the arithmetic circuit 300b are separated. With such a configuration, the pixel array unit 240b may include the imaging pixel circuit 250, the monitor pixel circuit 260, the VBD monitor circuit 270, the temperature monitor circuit 280, and the storage unit (memory) 290, so that versatility of the pixel array unit 240b is further improved.

### Second Embodiment

The ranging module 100 according to a second embodiment is different from the ranging module 100 according to the first embodiment in that an arithmetic circuit 300c further includes a VBD temporal change amount calculation unit 303 that corrects the breakdown voltage VBD(T) (see FIG. 6). Hereinafter, differences from the ranging module 100 according to the first embodiment will be described below.

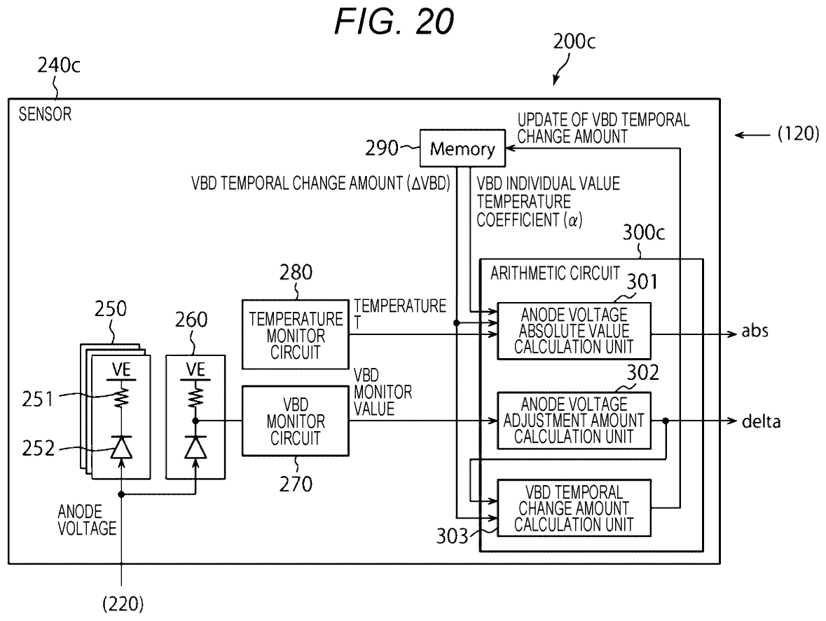

FIG. 20 is a block diagram illustrating a configuration example of a pixel array unit 240c according to the second embodiment. As illustrated in FIG. 20, the arithmetic circuit 300c further includes the VBD temporal change amount calculation unit 303.

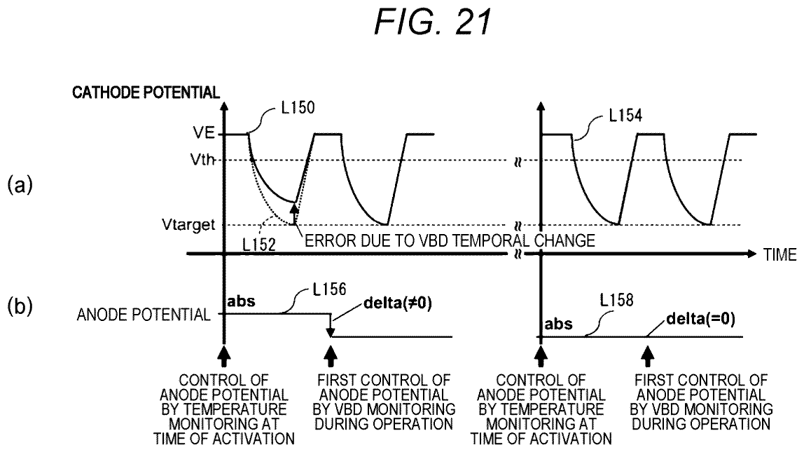

FIG. 21 is a diagram illustrating a temporal change of the cathode potential Vc and the anode potential Va of the photodiode 252. (a) of the drawing is a diagram illustrating the cathode potential Vc of the photodiode 252. The vertical axis represents the cathode potential Vc, and the horizontal axis represents time. A line L150 indicates a temporal change of the cathode potential before the correction of the breakdown voltage VBD(T). Furthermore, a line L152 indicates a temporal change of the cathode potential V in a case where the cathode potential V coincides with the target potential Vtarget at the time of activation. Furthermore, a line L154 indicates a temporal change of the cathode potential after correction of the breakdown voltage VBD(T).

(b) of the drawing is a diagram illustrating an anode potential of the photodiode 252. The vertical axis represents the m-anode potential Va, and the horizontal axis represents time. A line L156 indicates a temporal change of the anode potential Va before correction of the breakdown voltage VBD(T), and a line L158 indicates a temporal change of the anode potential Va after correction of the breakdown voltage VBD(T).

As illustrated in (a) of the drawing, when the breakdown voltage VBD(T) is accurate, the temporal change of the cathode potential Vc becomes the line L152. However, for example, a deviation may occur in the breakdown voltage VBD(T) due to a secular change. Therefore, a deviation at the bottom potential Vbtm occurs as in the line L150. As described above, the bottom potential Vbtm of the line L150 is monitored as the bottom potential Vbtm of the VBD monitor circuit 270. At this time, the adjustment value delta calculated by the anode potential adjustment amount calculation unit 302 is a value shown in Expression (3).

As can be seen from these, the calculated adjustment value delta becomes the potential generated by the deviation of the breakdown voltage VBD(T) following the activation. Furthermore, the temperature at this time is set as T0, and the initial adjustment value delta is set as a VBD temporal change amount ΔVBD(T0). The VBD temporal change amount calculation unit 303 stores the initial adjustment value delta in the storage unit 290 as the VBD temporal change amount ΔVBD(T0).

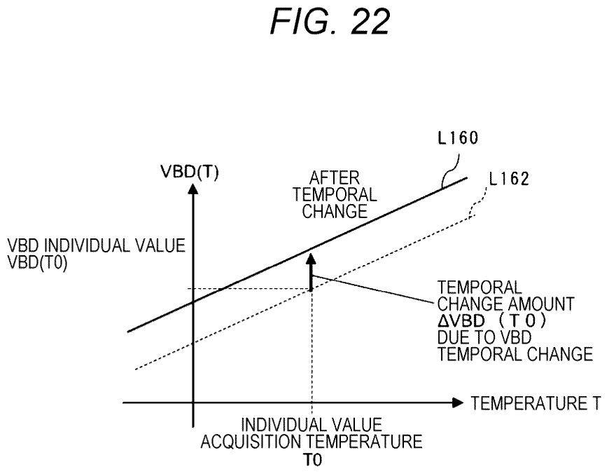

FIG. 22 is a diagram illustrating an example of temperature characteristics of the cathode potential Vc. The vertical axis represents the breakdown voltage VBD(T), and the horizontal axis represents temperature. A temperature characteristic line L160 after the temporal change of the breakdown voltage VBD(T) and a temperature characteristic line L162 before the temporal change of the breakdown voltage VBD(T) are illustrated. As illustrated in FIG. 22, the change in the individual value temperature coefficient a indicating the slope of the temperature characteristic line L160 is minute. Therefore, the anode potential absolute value calculation unit 301 adjusts the intercept value by adding the VBD temporal change amount ΔVBD(T0) as shown in Expression (4) so that the temperature characteristic line L160 after the temporal change coincides with the temperature characteristic line L162 before the temporal change.

[Math. 4]

VBDa(T)=VBD(T0)+α*{T−T0}+ΔVBD(T0) (4)

[Math. 5]

abs=(VE−Vtarget)−VBDa(T)+c (5)

The anode potential absolute value calculation unit 301 substitutes VBDa(T) in Expression (4) into Expression (1) to calculate the corrected anode potential abs in Expression (5).

As illustrated in FIG. 21, when the anode potential is controlled with the anode potential abs in Expression (5), the bottom potential Vbtm matches the target potential Vtarget as indicated by the line L154. The adjustment value delt at this time is 0.

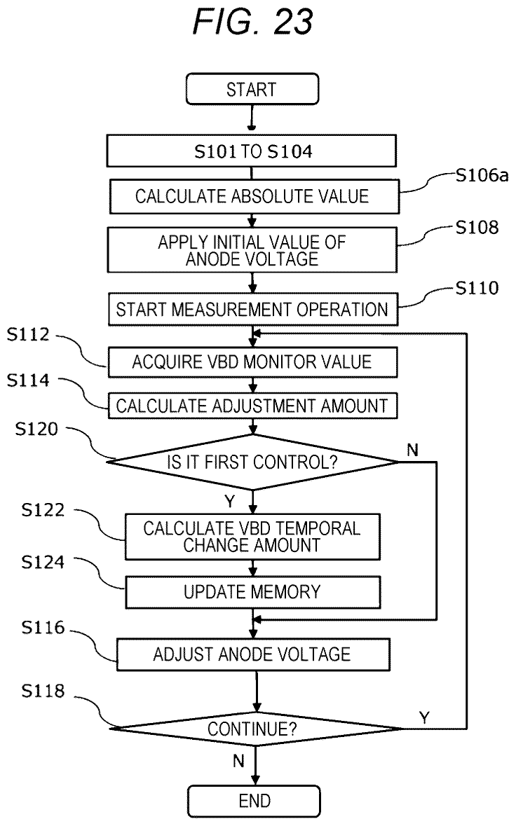

FIG. 23 is a flowchart illustrating an operation example of the photodetection element 200 according to the second embodiment. Processes equivalent to those in the flowchart illustrated in FIG. 17 are denoted by the same reference numerals, and description thereof is omitted. The processes of steps S101 to S104 are ended. Next, the anode potential absolute value calculation unit 301 substitutes VBDa(T) in Expression (4) into Expression (1) to calculate the corrected anode potential abs in Expression (5) (step S106a). Then, the control circuit 210 supplies the corrected anode potential abs in Expression (5) to the anode potential supply power source 220, and the anode potential supply power source 220 controls the potential of the anode of the photodiode 252 in the imaging pixel circuit 250 and the monitor pixel circuit 260 to the corrected anode potential abs (step S108).

Subsequently, after finishing the processing of steps S112 to S114, the VBD temporal change amount calculation unit 303 determines whether or not it is the first control following the driving (step S120). In a case where it is determined that the control is the first control following the driving (Y in step S120), the VBD temporal change amount calculation unit 303 stores the adjustment value delta (see Expression (3)) calculated by the anode voltage adjustment amount calculation unit 302 in the storage unit 190 as the VBD temporal change amount ΔVBD(T0).

On the other hand, in a case where it is determined that the control is not the first control (N in step S120), the VBD temporal change amount calculation unit 303 performs the process from S116.

As described above, according to the present embodiment, the VBD temporal change amount calculation unit 303 stores the adjustment value delta (see Expression (3)) in the first control in the storage unit 190 as the VBD temporal change amount ΔVBD(T0). Then, the control circuit 210 controls the anode potential of the photodiode 252 at the start of driving by the corrected anode potential abs in Expression (5) including the VBD temporal change amount ΔVBD(T0). Therefore, it is possible to suppress the deviation between the bottom potential Vbtm and the target potential Vtarget due to the temporal change of the photodiode 252.

### First Modification of Second Embodiment

A ranging module 100 according to a first modification of the second embodiment is different from the ranging module 100 according to the second embodiment in that a control circuit 210d includes a VBD temporal change amount calculation unit 303. Hereinafter, differences from the ranging module 100 according to the first embodiment will be described below.

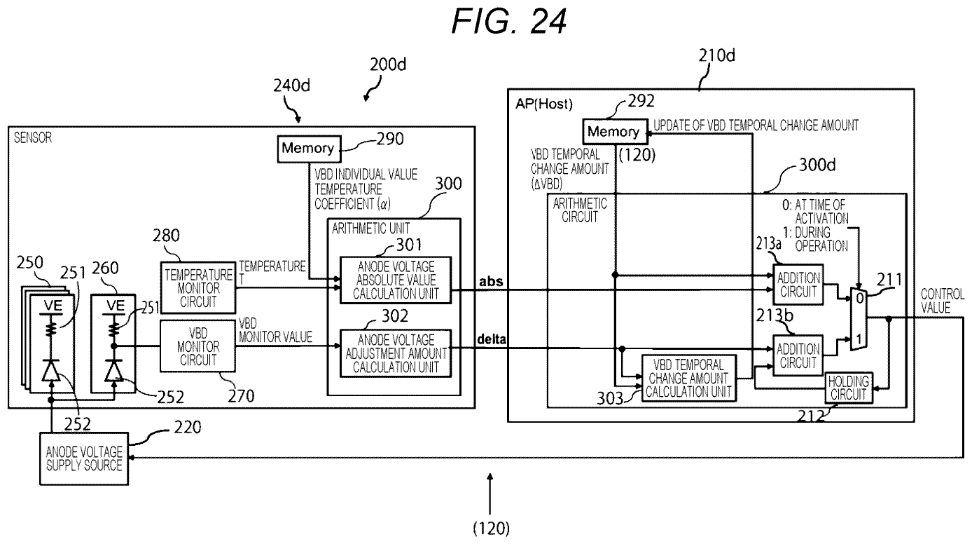

FIG. 24 is a diagram illustrating a configuration example of an imaging element 200 according to the second embodiment. As illustrated in FIG. 24, the control circuit 210d is different from the ranging module 100 according to the second embodiment in including a second storage unit 292, a first addition circuit 213a, a second addition circuit 213b, and a VBD temporal change amount calculation unit 303. The second storage unit 292 stores the VBD temporal change amount ΔVBD(T0).

[Math. 6]

abs2=abs−ΔVBD(T0) (6)

As indicated by Expression (6), the first addition circuit 213a adds the VBD temporal change amount ΔVBD(T0) of the second storage unit 292 to the anode potential abs indicated by Expression (3) to calculate an anode potential abs2. The selection circuit 211 outputs the anode potential abs2 as a control value at the time of activation.

On the other hand, the second addition circuit 213b adds the adjustment potential delta to the previous anode potential held in the holding circuit 212. During operation, the selection circuit 211 outputs the output value of the second addition circuit 213b as a control value.

As described above, according to the present embodiment, the VBD temporal change amount calculation unit 303 is configured in the control circuit 210d. Therefore, in addition to the effect of the ranging module 100 according to the first embodiment, it is possible to suppress the deviation between the bottom potential Vbtm and the target potential Vtarget due to the temporal change of the photodiode 252.

### Third Embodiment

The ranging module 100 according to the third embodiment is different from the ranging module 100 according to the second embodiment in that it includes a VBD temporal change amount calculation unit 303a with temperature change threshold determination. Hereinafter, differences from the ranging module 100 according to the second embodiment will be described below.

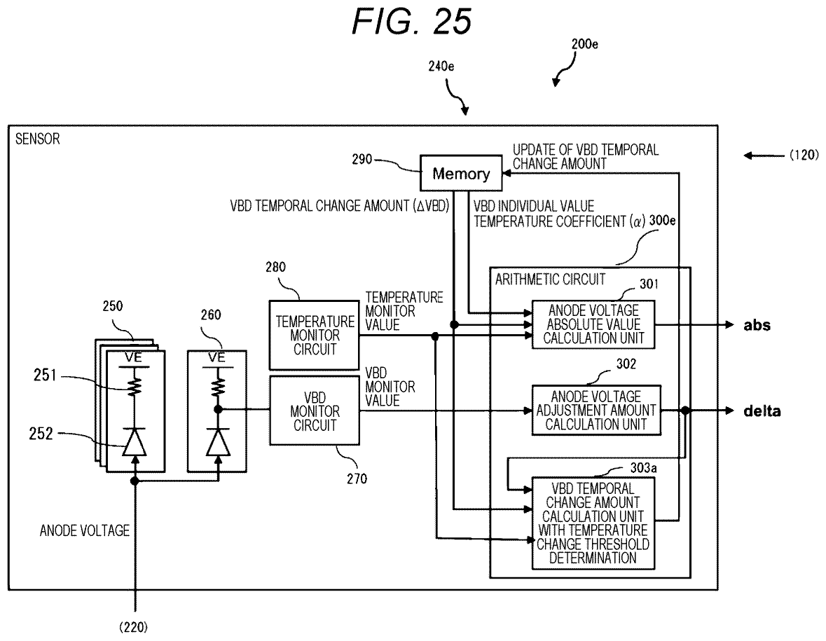

FIG. 25 is a block diagram illustrating a configuration example of a pixel array unit 240e according to the third embodiment. As illustrated in FIG. 25, an arithmetic circuit 300e includes the VBD temporal change amount calculation unit 303a with temperature change threshold determination.

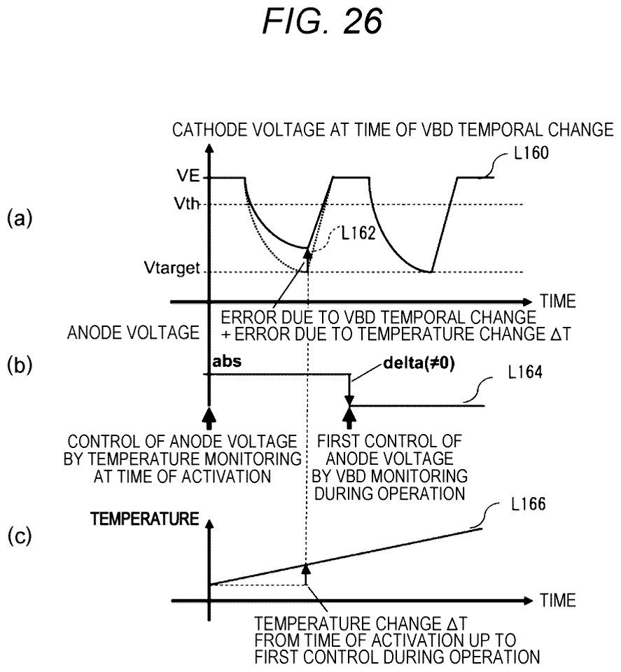

FIG. 26 is a diagram illustrating a temporal change of the cathode potential Vc, the anode potential Va, and the temperature T of the photodiode 252. (a) of the drawing is a diagram illustrating the cathode potential Vc of the photodiode 252. The vertical axis represents the cathode potential Vc, and the horizontal axis represents time. A line L160 indicates a temporal change of the cathode potential Vc before the correction of the breakdown voltage VBD(T). Furthermore, a line L162 indicates a temporal change of the cathode potential Vc in a case where the bottom potential Vbtm coincides with the target potential Vtarget at the time of activation.

(b) of the drawing is a diagram illustrating an anode potential of the photodiode 252. The vertical axis represents the anode potential Va, and the horizontal axis represents time. A line L164 indicates a temporal change of the anode potential Va before the correction of the breakdown voltage VBD(T). (c) of the drawing is a diagram illustrating the temperature of the photodiode 252. The vertical axis represents the temperature T, and the horizontal axis represents time. A line L166 indicates a temporal change of the temperature T of the photodiode 252.

As shown in Expressions (4) and (5), the VBD temporal change amount calculation unit 303a with temperature change threshold determination can set the adjustment value delta (see Expression (3)) in the first control as the VBD temporal change amount ΔVBD(T0). On the other hand, as illustrated in (c) of the drawing, there is a case where a temperature change AT occurs between the time of activation and the first control. The component α×ΔT of the VBD fluctuation due to the temperature change is added to the VBD temporal change amount ΔVBD(T0) at this time.

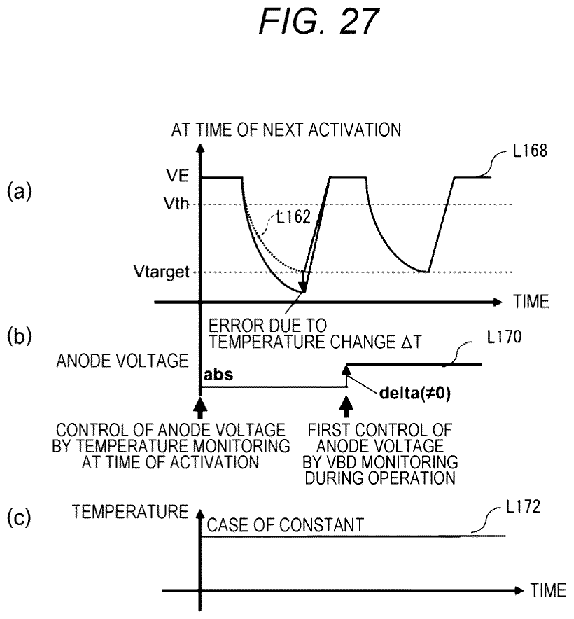

FIG. 27 is a diagram illustrating an operation example of the photodiode 252 at the time of driving using the VBD temporal change amount ΔVBD(T0) in a case where the temperature change ΔT occurs. (a) of the drawing is a diagram illustrating the cathode potential Vc of the photodiode 252. The vertical axis represents the cathode potential Vc, and the horizontal axis represents time. A line L168 indicates a temporal change of the cathode potential Vc after correction. Furthermore, a line L162 indicates a temporal change of the cathode potential in a case where the bottom potential Vbtm coincides with the target potential Vtarget at the time of activation.

(b) of the drawing is a diagram illustrating an anode potential Va of the photodiode 252. The vertical axis represents the anode potential Va, and the horizontal axis represents time. A line L170 indicates a temporal change of the anode potential Va after correction of the individual value temperature coefficient a. (c) of the drawing is a diagram illustrating the temperature of the photodiode 252. The vertical axis represents the temperature, and the horizontal axis represents time. A line L172 indicates a temporal change of the temperature of the photodiode 252.

As illustrated in (c) of the drawing, the temperature change of the line L172 is different from the temperature change of the line L166. Therefore, as indicated by a line L168 in (a) of the drawing, the cathode potential after correction of the breakdown voltage VBD(T) using the VBD temporal change amount ΔVBD(T0) in a case where the temperature change ΔT occurs deviates from the target potential Vtarget. Therefore, the VBD temporal change amount calculation unit 303a with temperature change threshold determination according to the present embodiment calculates the temperature change ΔT of a predetermined time width of the temperature monitor value of the temperature monitor circuit 280, and performs control not to update the VBD temporal change amount ΔVBD in a case where the temperature change ΔT exceeds the threshold.

More specifically, the VBD temporal change amount calculation unit 303a with temperature change threshold determination calculates a difference ΔT=(T1−T0) between the activation temperature T0 and the temperature T1 at the time of the first delta calculation during operation. Then, when the temperature difference ΔT is equal to or smaller than a temperature change threshold ΔTth, the VBD temporal change amount calculation unit 303a with temperature change threshold determination updates the VBD temporal change amount ΔVBD according to Expression (7) using the first delta during operation and the VBD temporal change amount ΔVBD read from the storage unit 290.

[Math. 7]

ΔVBD (updated value)=ΔVBD (value read from memory)−delta (first operation) (7)

On the other hand, when the temperature difference ΔT is equal to or larger than the temperature change threshold ΔTth, the VBD temporal change amount ΔVBD is not updated. By obtaining the VBD temporal change amount only when the temperature change is small, the bottom potential Vbtm can be accurately adjusted from the time of activation.

### First Modification of Third Embodiment

A ranging module 100 according to a first modification of the third embodiment is different from the ranging module 100 according to the third embodiment in that a control circuit 210f includes a VBD temporal change amount calculation unit 303a with temperature change threshold determination. Hereinafter, differences from the ranging module 100 according to the third embodiment will be described below.

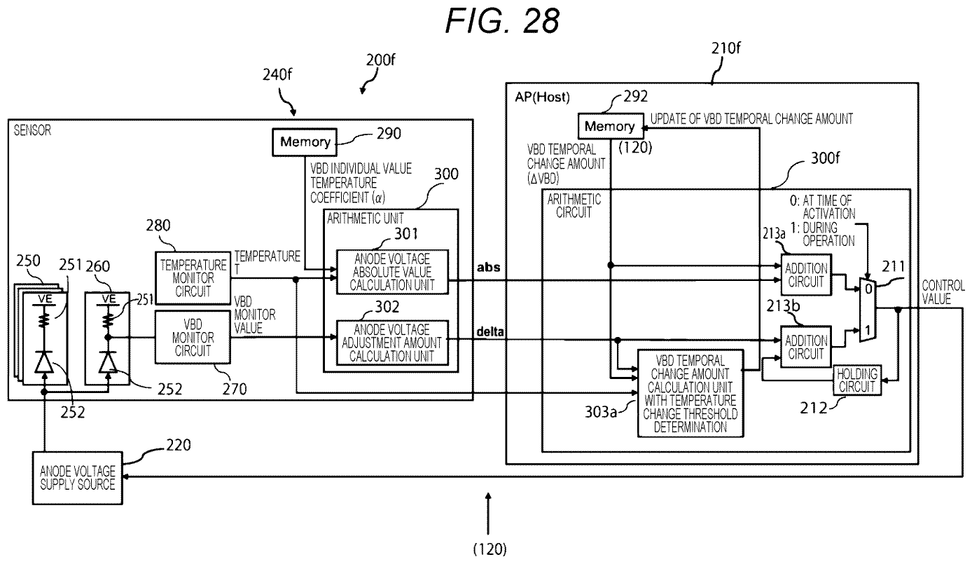

FIG. 28 is a diagram illustrating the configuration example of the imaging element 200 according to the second embodiment. As illustrated in FIG. 28, the control circuit 210f is different from the ranging module 100 according to the third embodiment in including a second storage unit 292, a first addition circuit 213a, a second addition circuit 213b, and a VBD temporal change amount calculation unit 303a with temperature change threshold determination. As described above, the second storage unit 292 stores the VBD temporal change amount ΔVBD(T0).

As indicated by Expression (6) described above, the first addition circuit 213a adds the VBD temporal change amount ΔVBD(T0) of the second storage unit 292 to the anode potential abs indicated by Expression (3) to calculate an anode potential abs2. The selection circuit 211 outputs the anode potential abs2 as a control value at the time of activation.

On the other hand, the second addition circuit 213b adds the adjustment potential delta to the previous anode potential held in the holding circuit 212. During operation, the selection circuit 211 outputs the output value of the second addition circuit 213b as a control value.

As described above, according to the present embodiment, the VBD temporal change amount calculation unit 303a with temperature change threshold determination is configured in the control circuit 210f. Therefore, in addition to the effect of the ranging module 100 according to the first embodiment, it is possible to suppress the deviation between the bottom potential Vbtm and the target potential Vtarget due to the temporal change of the photodiode 252, and it is possible to accurately adjust the bottom potential Vbtm from the activation by obtaining the VBD temporal change amount only when the temperature change is small.

### Fourth Embodiment

A ranging module 100 according to a fourth embodiment is different from the ranging module 100 according to the first embodiment in that the anode potential Va can be controlled using the information of the temperature monitor circuit 280 in a case where the photodiode 252 of the monitor pixel circuit 260 cannot generate the photocurrent to such an extent that the VBD monitor circuit 270 can maintain the accuracy. Hereinafter, differences from the ranging module 100 according to the first embodiment will be described below.

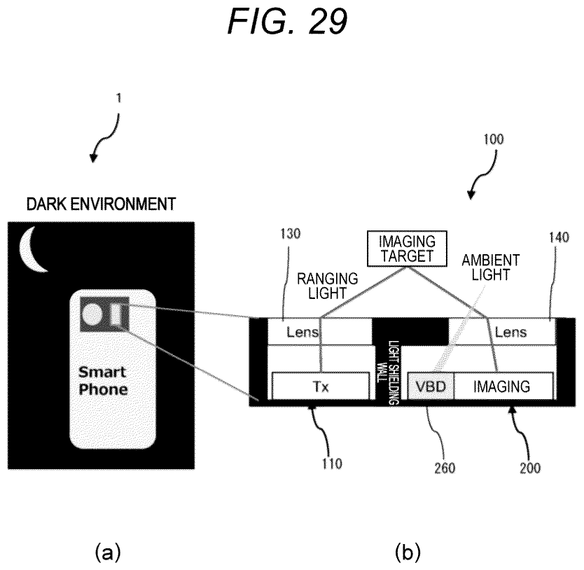

FIG. 29 is a block diagram illustrating a configuration example of the ranging module 100 according to the fourth embodiment of the present technology. The ranging module 100 is mounted on an electronic apparatus 1. The electronic apparatus 1 is a smartphone. (a) of the drawing is a diagram schematically illustrating a plan view of a smartphone. (b) of the drawing is a diagram schematically illustrating a cross-sectional view of the ranging module 100.

As illustrated in (b) of the drawing, the ranging module 100 includes optical systems 130 and 140. The light emitting unit 110 emits measurement light via the optical system 130. The photodetection element 200 receives return light from the object via the optical system 140. However, the photodiode 252 of the monitor pixel circuit 260 may not be able to generate photocurrent. For example, the return light does not hit the photodiode 252 of the monitor pixel circuit 260, or the ambient light is insufficient such as at night. In such a case, the anode potential Va cannot be appropriately controlled.

In such a case, as illustrated in FIG. 6, the breakdown voltage VBD(T) varies depending on the temperature. Therefore, as illustrated in FIG. 10, the anode-cathode voltage VEX fluctuates.

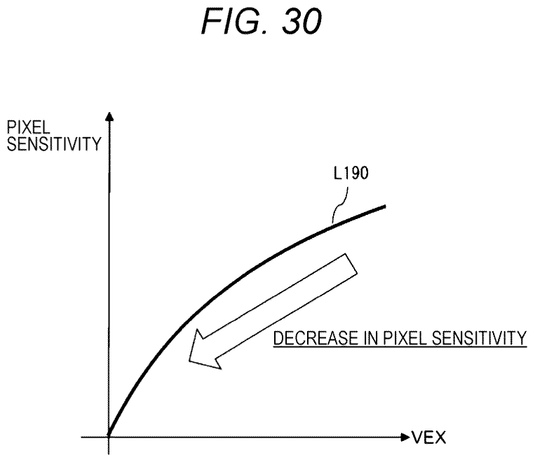

FIG. 30 is a diagram illustrating the relationship between the anode-cathode voltage VEX and the pixel sensitivity of the imaging pixel circuit 250. The vertical axis represents the sensitivity, and the horizontal axis represents the anode-cathode voltage VEX. As indicated by a variation curve L190 of the pixel sensitivity, the pixel sensitivity decreases as the anode-cathode voltage VEX decreases.

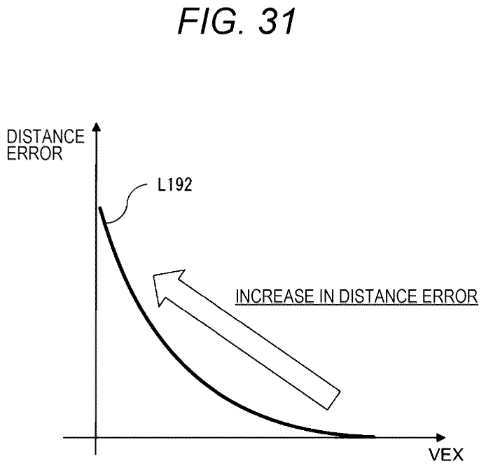

FIG. 31 is a diagram illustrating the relationship between the anode-cathode voltage VEX and the distance error of the imaging pixel circuit 250. The vertical axis represents the distance error, and the horizontal axis represents the anode-cathode voltage VEX. As indicated by a variation curve L192 of the distance error, the distance error increases as the anode-cathode voltage VEX decreases. As described above, in a case where the anode-cathode voltage VEX is not controlled within an appropriate range, the distance error of the imaging pixel circuit 250 increases.

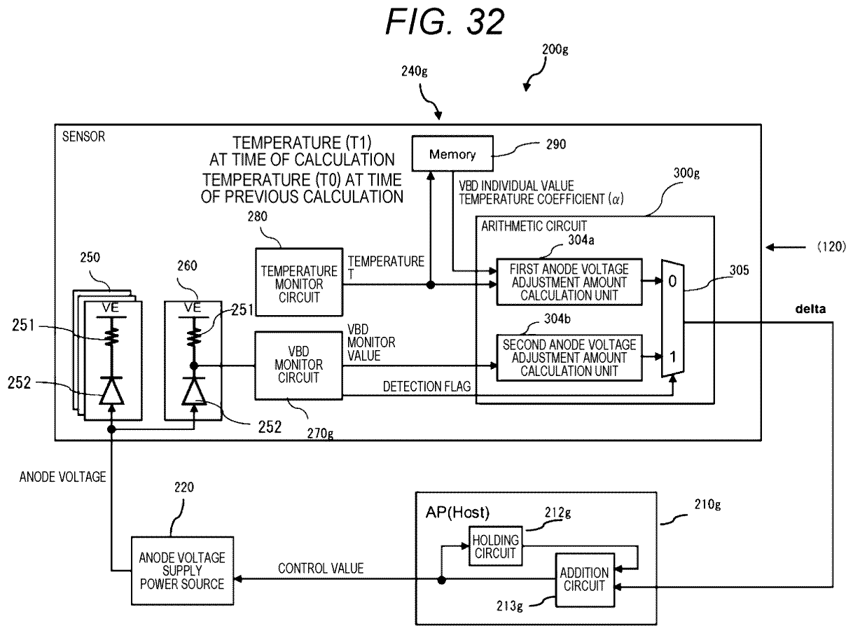

FIG. 32 is a cross-sectional view illustrating a configuration example of a photodetection element 200k according to the fourth embodiment. As illustrated in FIG. 32, a VBD monitor circuit 270k generates Flag 1 in a case where a photocurrent in a range measurable by the photodiode 252 of the monitor pixel circuit 260 is generated. On the other hand, Flag 0 is generated at the time of activation and in a case where the photodiode 252 does not generate a photocurrent in the measurable range. The monitor pixel circuit 260 outputs the flag to a selection unit 305 of an arithmetic circuit 300g.

A VBD monitor circuit 270g generates Flag 1, for example, in a case where the cathode potential Vc exceeds the threshold potential Vth illustrated in FIG. 7 or the like. On the other hand, in a case where the cathode potential does not exceed the threshold potential, Flag 0 is generated.

The arithmetic circuit 300g includes a first anode voltage adjustment amount calculation unit 304a, a second anode voltage adjustment amount calculation unit 304b, and a selection unit 304. The first anode voltage adjustment amount calculation unit 304a can perform the same operation as the anode potential absolute value calculation unit 301 (see FIG. 3) at the time of activation. Therefore, at the time of activation, the anode potential abs is calculated according to Expressions (1) and (2).

[Math. 8]

delta=−α×(T−1a−T1b) (8)

Furthermore, the first anode voltage adjustment amount calculation unit 304a acquires a temperature T1 from the temperature monitor circuit 280 at the time of calculation, and causes the storage unit 290 to hold the temperature T1. That is, even during the operation, the first anode voltage adjustment amount calculation unit 304a calculates the adjustment value delta of the anode potential according to Expression (8) when the flag is 0.

The temperature T1b is a temperature at the time of the previous calculation, and T1a is a temperature at the time of the current calculation. As illustrated in FIG. 6, since the breakdown voltage VBD(T) has a slope of the coefficient a depending on the temperature and varies substantially linearly, the temperature fluctuation of the bottom potential Vbtm depending on the breakdown voltage VBD(T) can be suppressed by using the temperature difference (T1a−T1b). Therefore, if the bottom potential Vbtm has a value equivalent to the target potential Vtarget at the temperature T1b, the bottom potential Vbtm has a value equivalent to the target potential Vtarget also at the temperature T1a.

The second anode voltage adjustment amount calculation unit 304b has the same configuration as the anode voltage adjustment amount calculation unit 302 (see FIG. 3). That is, the second anode voltage adjustment amount calculation unit 304b calculates the adjustment value delta according to Expression (3) when the flag is set to 1.

The selection unit 305 outputs the adjustment value delta generated by the first anode voltage adjustment amount calculation unit 304a when the flag is 0, and outputs the adjustment value delta generated by the second anode voltage adjustment amount calculation unit 304b when the flag is 1.

A control circuit 210g includes a holding circuit 212g and an addition circuit 213g. The holding circuit 212g holds and updates the output value of the addition circuit 213g. The holding circuit 212g is reset to 0 at the time of activation. Therefore, the anode potential abs in Expression (2) is stored at the time of activation. From the second time, the addition circuit 213g adds the adjustment value delta to the value held by the holding circuit 212g. That is, the anode potential abs is sequentially adjusted by the adjustment value delta.

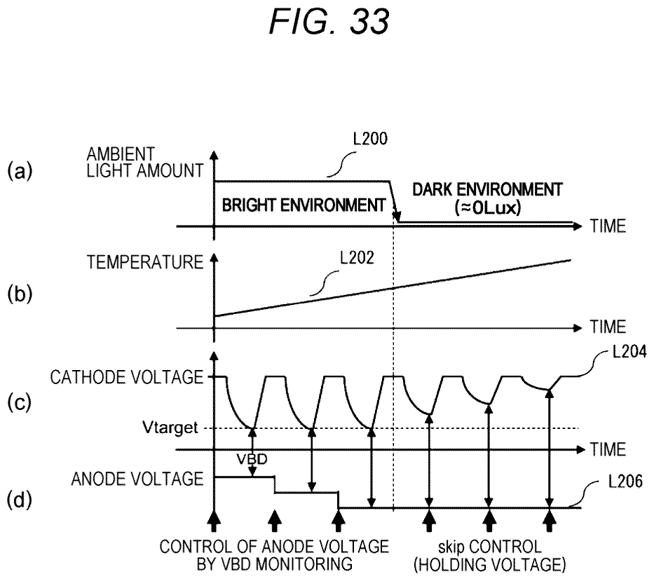

FIG. 33 is a diagram illustrating an example in which control is performed with all flags set to 1 except at the time of activation. (a) of the drawing is a diagram illustrating a variation L200 of the ambient light amount. The vertical axis represents the ambient light amount, and the horizontal axis represents time.

(b) of the drawing is a diagram illustrating a variation L202 of the temperature T acquired from the temperature monitor circuit 280. The vertical axis represents the temperature T, and the horizontal axis represents time. (c) of the drawing is a diagram illustrating a variation L204 of the cathode potential Vc of the photodiode 252. The vertical axis represents the cathode potential Vc, and the horizontal axis represents time. (d) of the drawing is a diagram illustrating a variation L206 of the anode potential Va of the photodiode 252. The vertical axis represents the anode potential Va, and the horizontal axis represents time.

As can be seen from these drawings, the VBD monitor circuit 270 functions under a bright environment, and the bottom potential Vbtm of the cathode potential Vc substantially matches the target potential Vtarget. On the other hand, the VBD monitor circuit 270 does not function under a dark environment, the anode potential becomes a constant value, and the bottom potential Vbtm rises according to temperature fluctuation.

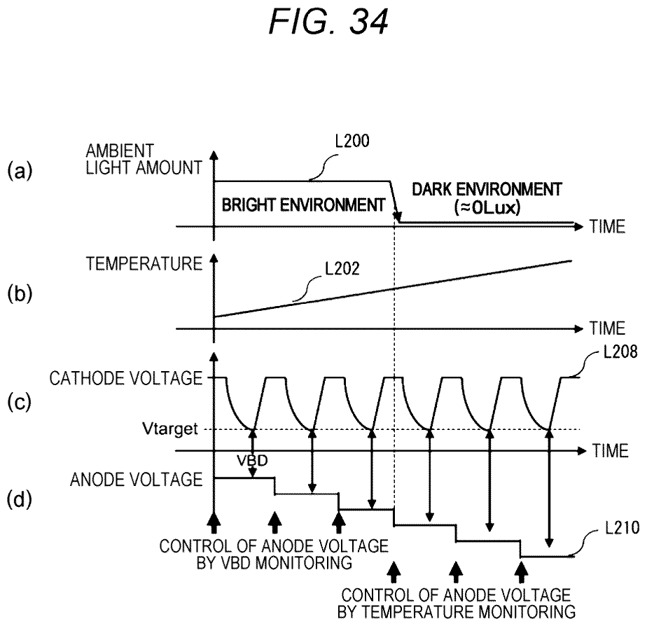

FIG. 34 is a diagram illustrating an example in which control using the temperature T is performed when the flag is set to 0 in a case where the VBD monitor circuit 270 does not function. (a) of the drawing is a diagram illustrating a variation L200 of the ambient light amount. The vertical axis represents the ambient light amount, and the horizontal axis represents time.

(b) of the drawing is a diagram illustrating a variation L202 of the temperature T acquired from the temperature monitor circuit 280. The vertical axis represents the temperature T, and the horizontal axis represents time. (c) of the drawing is a diagram illustrating a variation L208 of the cathode potential Vc of the photodiode 252. The vertical axis represents the cathode potential Vc, and the horizontal axis represents time. (d) of the drawing is a diagram illustrating a variation L210 of the anode potential Va of the photodiode 252. The vertical axis represents the anode potential Va, and the horizontal axis represents time.

In FIG. 34, even in a case where the VBD monitor circuit 270 does not function under a dark environment, the control using the temperature according to Expression (7) is performed. Therefore, the anode potential is controlled to an appropriate value, and the bottom potential Vbtm becomes a value equivalent to the target potential Vtarget even if temperature fluctuation occurs. As described above, even in a case where the VBD monitor circuit 270 does not function, the anode-cathode voltage VEX can be maintained at an appropriate value even in a case where the temperature T fluctuates by performing the control using the temperature according to Expression (7), and a decrease in measurement accuracy is suppressed. In this way, a decrease in sensitivity and a distance deviation are suppressed.

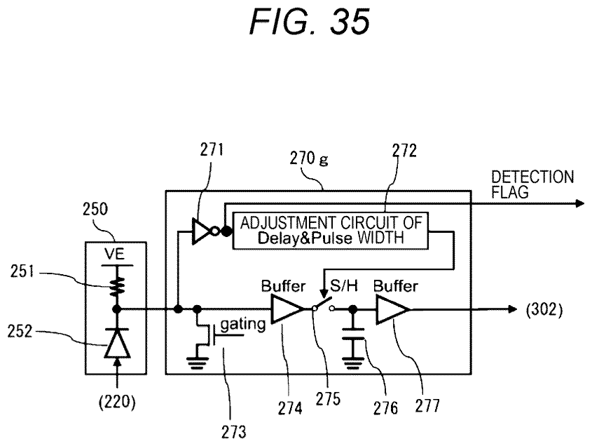

FIG. 35 is a diagram illustrating a configuration example of a VBD monitor circuit 270g according to the fourth embodiment. The VBD monitor circuit is different from the VBD monitor circuit 270 according to the first embodiment in that the output of the inverter 271 is output as a detection flag. As described above, the inverter 271 outputs 1 that is a high level in a case where the cathode potential Vc exceeds the threshold potential Vth, and outputs 0 that is a low level in a case where the cathode potential Vc does not exceed the threshold potential Vth. Therefore, it is possible to determine whether or not the VBD monitor circuit 270g is functioning.

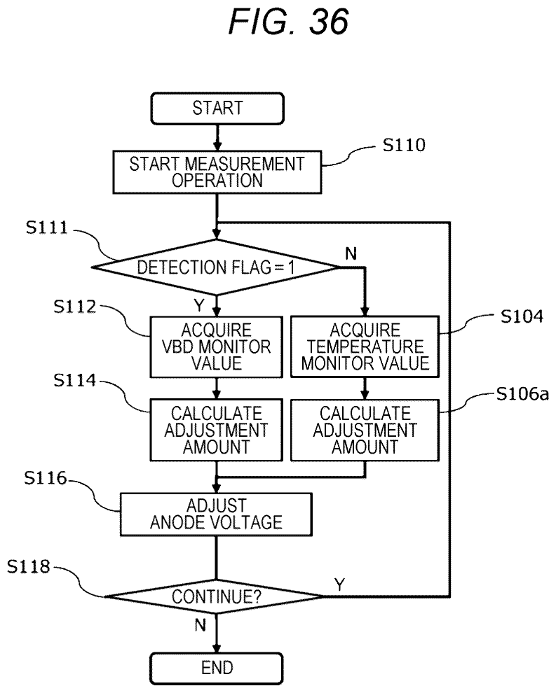

FIG. 36 is a flowchart illustrating an example of control processing during the measurement operation in the present embodiment. Processes equivalent to those in FIG. 17 are denoted by the same reference numerals, and description thereof is omitted. When the measurement operation is turned, the VBD monitor circuit 270 outputs the detection flag. In a case where the detection flag is 1 (Y in step S111), the second anode voltage adjustment amount calculation unit 304b acquires the bottom potential Vbtm monitored by the BD monitor circuit 270 when the flag is 1 (step S112), and the second anode voltage adjustment amount calculation unit 304b calculates the adjustment value delta according to Expression (3).

On the other hand, in a case where the detection flag is 0 (N in step S111), the first anode voltage adjustment amount calculation unit 304a acquires the temperature T1 from the temperature monitor circuit 280 (step S104). Then, the first anode voltage adjustment amount calculation unit 304a calculates the adjustment value delta of the anode potential according to Expression (7) (step S106a).

As described above, in a case where the VBD monitor circuit 270 cannot maintain the accuracy, the ranging module 100 according to the present embodiment controls the anode potential Va using the temperature T of the temperature monitor circuit 280. Therefore, even in a case where the photodiode 252 of the monitor pixel circuit 260 cannot generate an appropriate amount of photocurrent, the bottom potential Vbtm can be brought close to the target voltage Vtarget, and a decrease in the measurement accuracy of the ranging module 100 is suppressed.

### First Modification of Fourth Embodiment

A ranging module 100 according to a first modification of the fourth embodiment is different from the ranging module 100 according to the fourth embodiment in that an arithmetic circuit 300h also has a circuit configuration of a control circuit 210g. Hereinafter, differences from the ranging module 100 according to the fourth embodiment will be described below.

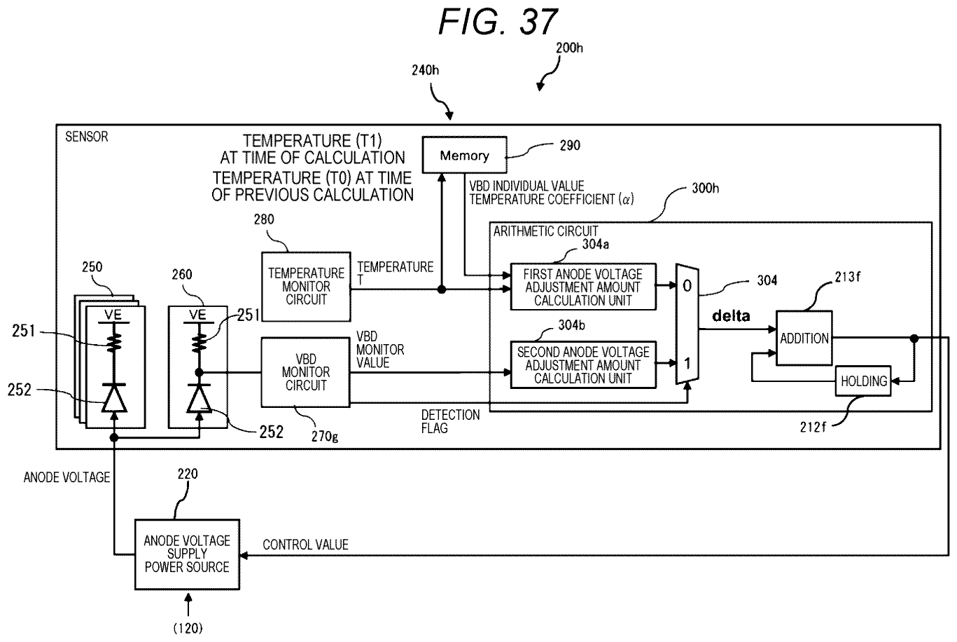

FIG. 37 is a diagram illustrating a configuration example of a pixel array unit 240h and a control circuit 210h according to the first modification of the fourth embodiment. As illustrated in FIG. 37, the ranging module is different from the ranging module 100 according to the fourth embodiment in that the arithmetic circuit 300h also has a circuit configuration of the control circuit 210g. With such a configuration, by integrating the circuit configuration of a control circuit 210j and the circuit configuration of the arithmetic circuit 300h in the same element, a photodetection element 200a can be further downsized.

### Second Modification of Fourth Embodiment

A ranging module 100 according to a second modification of the fourth embodiment is different from the ranging module 100 according to the fourth embodiment in that the control circuit 210j also has a circuit configuration of the arithmetic circuit 300h, and the pixel array unit 240b and the control circuit 210j are separated. Hereinafter, differences from the ranging module 100 according to the fourth embodiment will be described below.

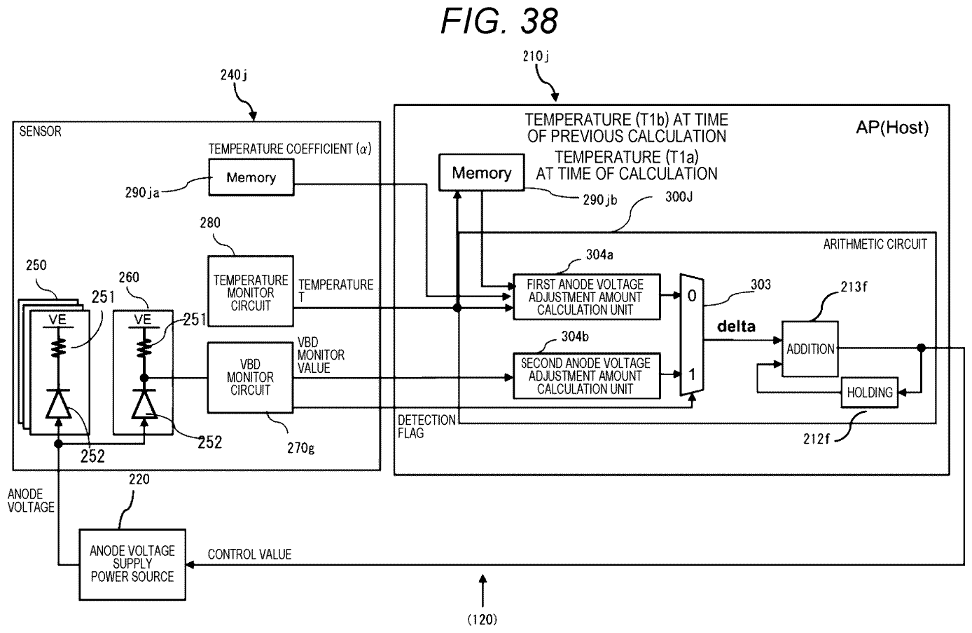

FIG. 38 is a diagram illustrating a configuration example of a pixel array unit 240j and the control circuit 210j according to the second modification of the fourth embodiment. The ranging module is different from the ranging module 100 according to the fourth embodiment in that the circuit configuration of the arithmetic circuit 300h is also included in the control circuit 210j, and the pixel array unit 240b and the control circuit 210j are separated. Furthermore, a storage unit 240jb is configured on the control circuit 210j side, and stores the temperatures T1b and T1a.

With such a configuration, the pixel array unit 240j may include the imaging pixel circuit 250, the monitor pixel circuit 260, the VBD monitor circuit 270, the temperature monitor circuit 280, and the storage unit (memory) 290, so that versatility of the pixel array unit 240j is further improved.

### Fifth Embodiment

A ranging module 100 according to a fifth embodiment is different from the ranging module 100 according to the fourth embodiment in that the VBD monitor circuit 270k includes the circuit configurations of a smoothing circuit 400, a reaction number counter 402, and a threshold determination circuit 404 in the control circuit 210j. Hereinafter, differences from the ranging module 100 according to the fourth embodiment will be described below.

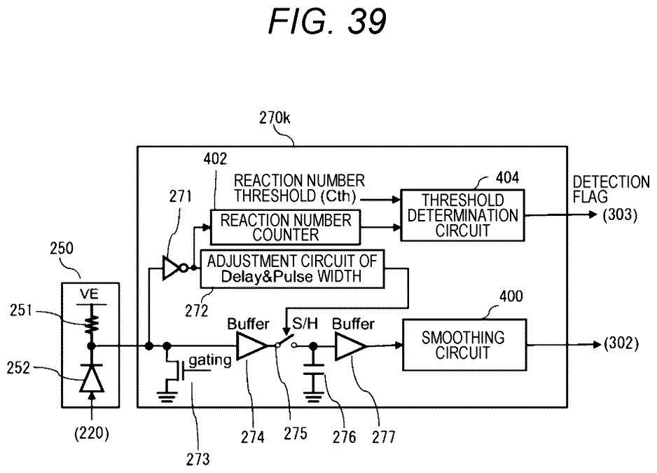

FIG. 39 is a diagram illustrating a circuit configuration example of the VBD monitor circuit 270k according to the fifth embodiment. As illustrated in FIG. 39, a difference from the ranging module 100 according to the fourth embodiment will be described in that the VBD monitor circuit 270k includes the smoothing circuit 400, the reaction number counter 402, and the threshold determination circuit 404.

The smoothing circuit 400 suppresses noise by adding the bottom potential Vbtm output from the VBD monitor circuit 270k a plurality of times, for example. The smoothing circuit 400 includes, for example, IIR/FIR.

The reaction number counter 402 counts the pulse signal output from the inverter 271. The threshold determination circuit 404 outputs the detection flag in a case where the number of times counted by the reaction number counter 402 exceeds a reaction number threshold Cth. With such a configuration, when the number of measurements exceeding the reaction number threshold Cth after the start of measurement ends, the detection flag 1 is output.

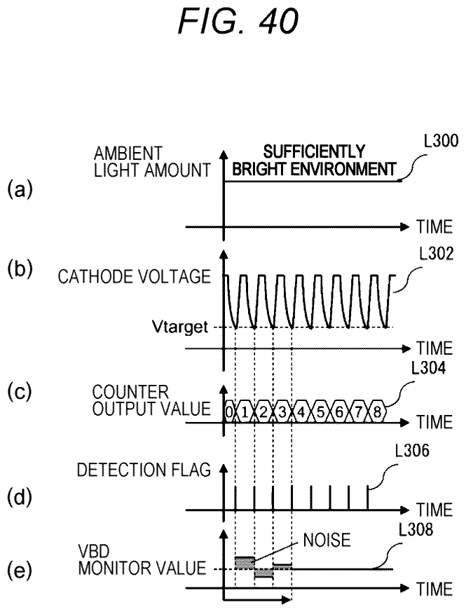

FIG. 40 is a diagram illustrating a change in the bottom potential Vbtm which is the VBD monitor value output by the VBD monitor circuit 270k in a case where the reaction number threshold Cth is set to 1 time. (a) of the drawing is a diagram illustrating a variation L300 of the ambient light amount. The vertical axis represents the ambient light amount, and the horizontal axis represents time.

(b) in the drawing is a diagram illustrating a variation L302 of the cathode potential Vc of the photodiode 252. The vertical axis represents the cathode potential Vc, and the horizontal axis represents time. (c) of the drawing is a diagram illustrating a counter value L304 of the reaction number counter 402. The vertical axis represents the cathode potential Vc, and the horizontal axis represents time. (d) of the drawing is a diagram illustrating a variation L306 of the detection flag. The vertical axis represents the high level of the detection flag, and the horizontal axis represents time. (e) of the drawing is a diagram illustrating a variation L308 of the VBD monitor value. The vertical axis represents the VBD monitor value, and the horizontal axis represents time.

As illustrated in (a) of the drawing, the ambient light amount is sufficient, and the BD monitor circuit 270k functions a lot. As illustrated in (a) of the drawing, since the threshold is set to 1, the detection flag is output from the start of the measurement operation. On the other hand, as indicated by a line L308 in (e) of the drawing, the smoothing circuit 400 does not sufficiently function from the zeroth to third time, and the VBD monitor value is affected by noise. Therefore, the control of the anode potential Va of the photodiode 252 is also affected by noise from the start of the measurement operation to the zeroth to third time.

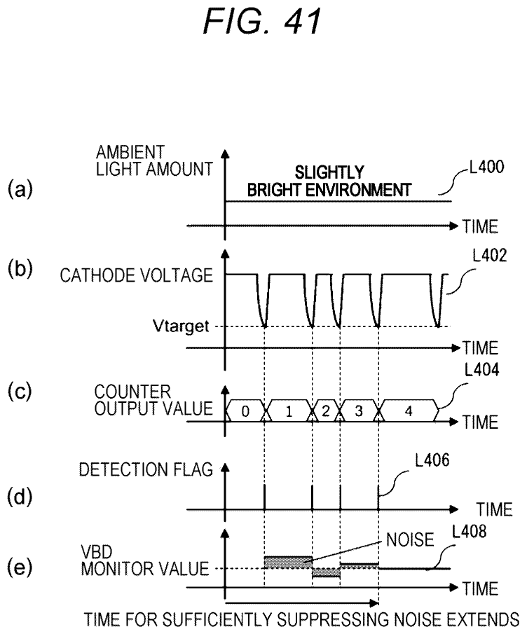

FIG. 41 is a diagram illustrating a change in the VBD monitor value in a slightly bright environment with the reaction number threshold Cth set to 1. (a) of the drawing is a diagram illustrating a variation L400 of the ambient light amount. The vertical axis represents the ambient light amount, and the horizontal axis represents time.

(b) of the drawing is a diagram illustrating a variation L402 of the cathode potential Vc of the photodiode 252. The vertical axis represents the cathode potential Vc, and the horizontal axis represents time. (c) of the drawing is a diagram illustrating a counter value L404 of the reaction number counter 402. The vertical axis represents the cathode potential Vc, and the horizontal axis represents time. (d) of the drawing is a diagram illustrating a variation L406 of the detection flag. The vertical axis represents the high level of the detection flag, and the horizontal axis represents time. (e) of the drawing is a diagram illustrating a variation L408 of the VBD monitor value. The vertical axis represents the VBD monitor value, and the horizontal axis represents time.

As illustrated in (a) of the drawing, the ambient light amount is a slightly bright environment. Under such an environment, the number of received photons statistically decreases. Therefore, as illustrated in (b) of the drawing, the number of times of variations of the cathode potential Vc is reduced as illustrated in a line L402. Therefore, as indicated by the line L404 in (c) of the drawing, the change in the counter number also increases the interval. On the other hand, as indicated by a line L408 in (e) of the drawing, the smoothing circuit 400 does not sufficiently function from the zeroth to third time, and the VBD monitor value is affected by noise. Therefore, the control of the anode potential Va of the photodiode 252 is also affected by noise from the start of the measurement operation to the zeroth to third time.

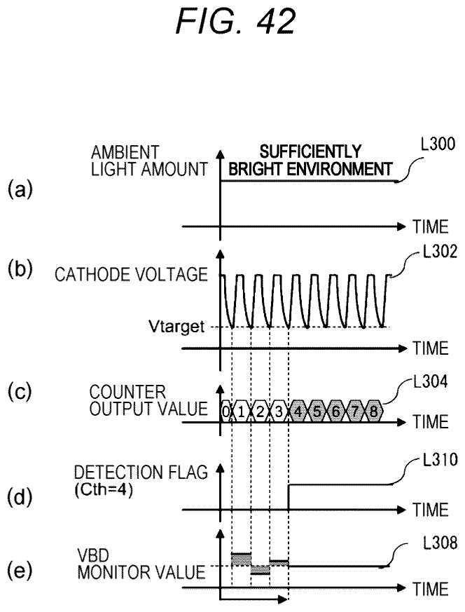

FIG. 42 is a diagram illustrating a change in the VBD monitor value output by the VBD monitor circuit 270k in a case where the reaction number threshold Cth is set to 4 times. (a) to (c) and (e) of the drawing are the same as those in FIG. 40. On the other hand, in (d) of the drawing, since the threshold of the variation L310 of the detection flag is set to 4, the detection flag 0 is output until the third measurement. Therefore, the smoothing circuit 400 does not function sufficiently, and the anode potential Va is controlled using the temperature T based on the adjustment value delta generated by the first anode voltage adjustment amount calculation unit 304a until the third measurement count at which the VBD monitor value is affected by noise. Therefore, the anode potential Va can be controlled without being affected by noise.

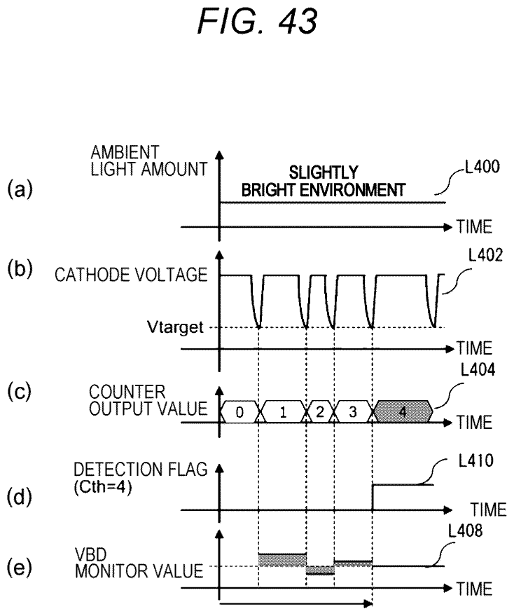

FIG. 43 is a diagram illustrating a change in the VBD monitor value output by the VBD monitor circuit 270k in a case where the reaction number threshold Cth is set to 4 times. (a) to (c) and (e) of the drawing are the same as those in FIG. 41. On the other hand, in (d) of the drawing, since the threshold of a variation L410 of the detection flag is set to 4, the detection flag 0 is output until the third measurement. Therefore, the smoothing circuit 400 does not function sufficiently, and the anode potential Va is controlled using the temperature T based on the adjustment value delta generated by the first anode voltage adjustment amount calculation unit 304a (see FIG. 32) until the third measurement count at which the VBD monitor value is affected by noise. Therefore, the anode potential Va can be controlled without being affected by noise.

As described above, at the start of measurement in which the control by the adjustment value delta generated by the second anode voltage adjustment amount calculation unit 304b (see FIG. 32) is affected by noise, the anode potential Va is controlled using the temperature T by the adjustment value delta generated by the first anode voltage adjustment amount calculation unit 304a (see FIG. 32). Therefore, the influence of noise at the start of measurement is suppressed, and a decrease in measurement accuracy is suppressed.

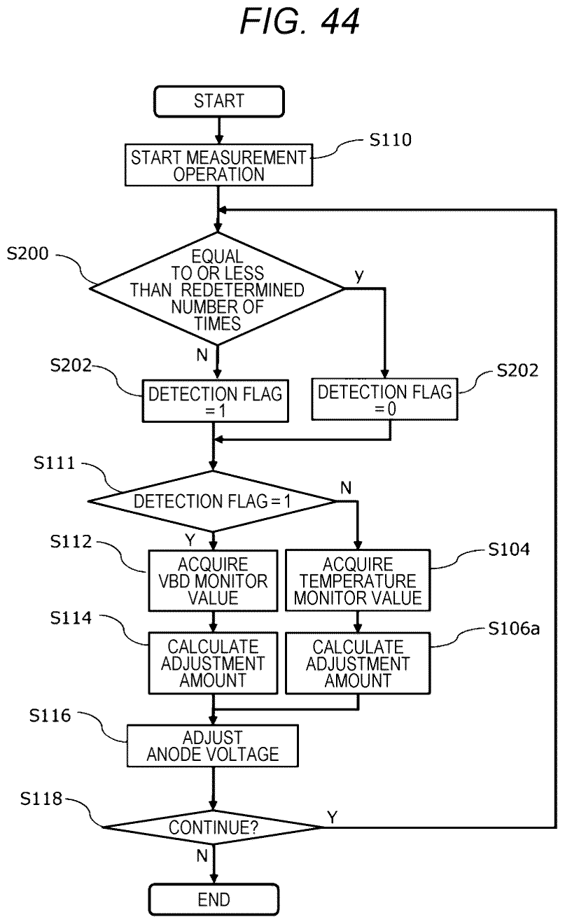

FIG. 44 is a flowchart illustrating an example of control processing during a measurement operation according to the fifth embodiment. Processes equivalent to those in FIG. 36 are denoted by the same reference numerals, and description thereof is omitted. The threshold determination circuit 404 determines whether or not the counter value of the reaction number counter 402 is equal to or less than a predetermined number of times, for example, equal to or less than 3 (step S200). If the counter value is equal to or less than the predetermined number of times (Y in step S111), the threshold determination circuit 404 sets the detection flag to 0. On the other hand, the threshold determination circuit 404 sets the detection flag to 1 if the counter value is not equal to or less than the predetermined number of times (N in step S111). Thereafter, processing equivalent to that in FIG. 36 is executed.

As described above, the ranging module 100 according to the present embodiment controls the anode potential Va using the temperature T of the temperature monitor circuit 280 when the counter value is equal to or less than the predetermined number of times after starting the measurement operation. Therefore, even in a case where there is a possibility that the smoothing circuit 400 cannot maintain the processing accuracy, the bottom potential Vbtm can be brought close to the target voltage Vtarget, and a decrease in the measurement accuracy of the ranging module 100 is suppressed.

### Sixth Embodiment

A ranging module 100 according to a sixth embodiment is different from the ranging module 100 according to the first embodiment in that the VBD monitor circuit 270g supplies a detection flag to the control circuit 210. Hereinafter, differences from the ranging module 100 according to the first embodiment will be described below.

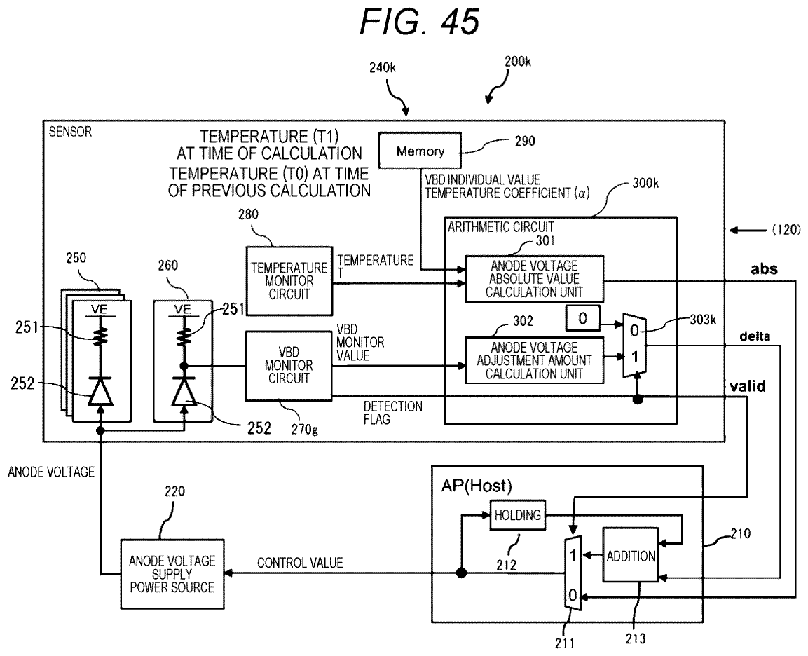

FIG. 45 is a block diagram illustrating a configuration example of a pixel array unit 240k in the sixth embodiment of the present technology. The VBD monitor circuit 270g according to the sixth embodiment is different from the ranging module 100 according to the first embodiment in that it has the same configuration as the VBD monitor circuit 270g according to the fourth embodiment. Therefore, the VBD monitor circuit 270g supplies the detection flag to the control circuit 210. Furthermore, an arithmetic circuit 300k further includes a selection unit 303h. The selection unit 303k outputs the output of the anode voltage adjustment amount calculation unit 302 to the control circuit 210 when the detection flag is 1. Note that the VBD monitor circuit 270k according to the fifth embodiment can be used instead of the VBD monitor circuit 270g.

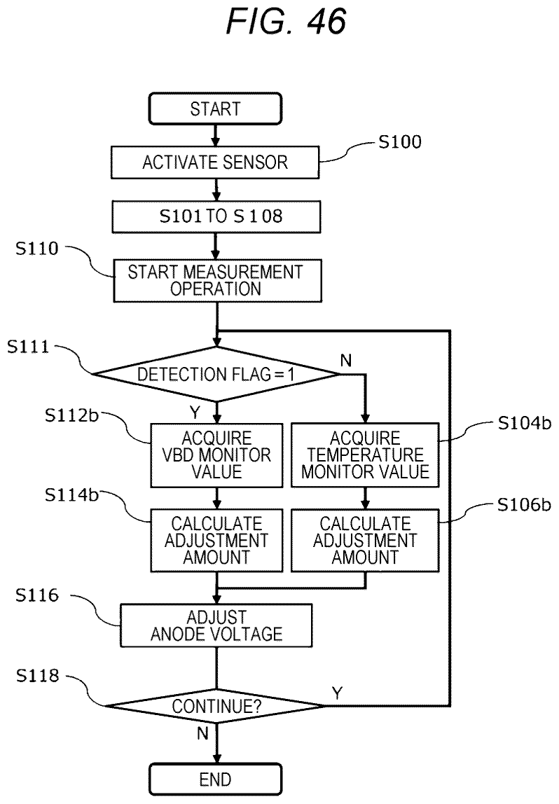

FIG. 46 is a flowchart illustrating an example of control processing according to the sixth embodiment. Processes equivalent to those in FIG. 17 are denoted by the same reference numerals, and description thereof is omitted. When the measurement operation is turned, the VBD monitor circuit 270 outputs the detection flag. In a case where the detection flag is 1 (Y in step S111), the anode voltage adjustment amount calculation 302 acquires the bottom potential Vbtm monitored by the BD monitor circuit 270 when the flag is 1 (step S112b), and the anode voltage adjustment amount calculation 302 calculates the adjustment value delta according to Expression (3) (step S114b).

On the other hand, in a case where the detection flag is 0 (N in step S111), the anode voltage absolute value calculation 301 acquires the temperature Tl from the temperature monitor circuit 280 (step S104b). Then, the anode voltage absolute value calculation 301 calculates the adjustment value delta of the anode potential according to Expression (7) (step S106b).

As described above, in a case where the VBD monitor circuit 270 cannot maintain the accuracy, the ranging module 100 according to the present embodiment controls the anode potential Va using the temperature T of the temperature monitor circuit 280. Therefore, even in a case where the photodiode 252 of the monitor pixel circuit 260 cannot generate an appropriate amount of photocurrent, the bottom potential Vbtm can be brought close to the target voltage Vtarget, and a decrease in the measurement accuracy of the ranging module 100 is suppressed.

### First Modification of Sixth Embodiment

A ranging module 100 according to a first modification of the sixth embodiment is different from the ranging module 100 according to the sixth embodiment in that a control circuit 210k according to the sixth embodiment is integrally configured in an arithmetic circuit 300L. Hereinafter, differences from the ranging module 100 according to the sixth embodiment will be described below.

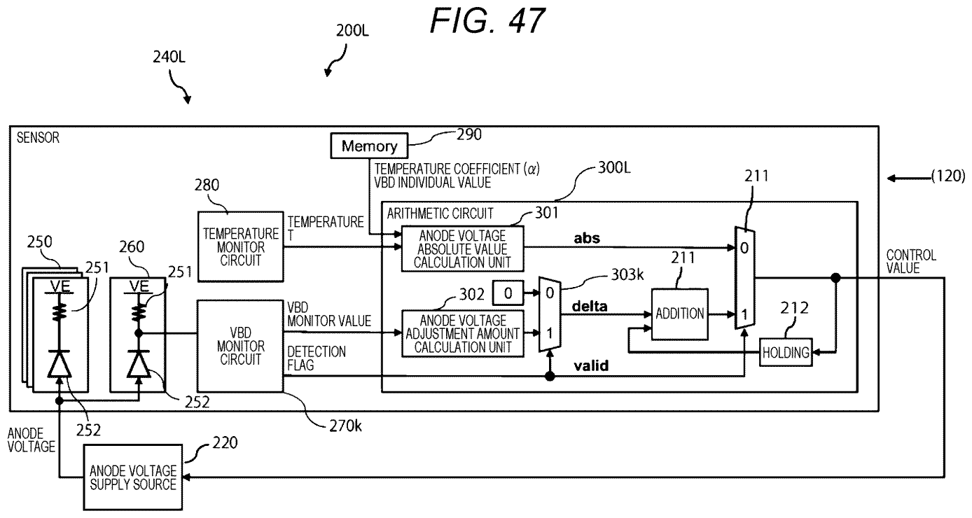

FIG. 47 is a block diagram illustrating a configuration example of a photodetection element 240L according to the first modification of the sixth embodiment of the present technology. The ranging module is different from the ranging module 100 according to the sixth embodiment in that the control circuit 210k is integrally configured in the arithmetic circuit 300L. As described above, the control circuit 210k is integrally configured in the arithmetic circuit 300L, so that the circuit configuration can be further downsized.

### Second Modification of Sixth Embodiment

A ranging module 100 according to a second modification of the sixth embodiment is different from the ranging module 100 according to the first modification of the sixth embodiment (see FIG. 47) in that a control circuit 210m according to the second modification of the sixth embodiment is separated from a pixel array unit 240m. Hereinafter, differences from the ranging module 100 according to the first modification of the sixth embodiment will be described below.

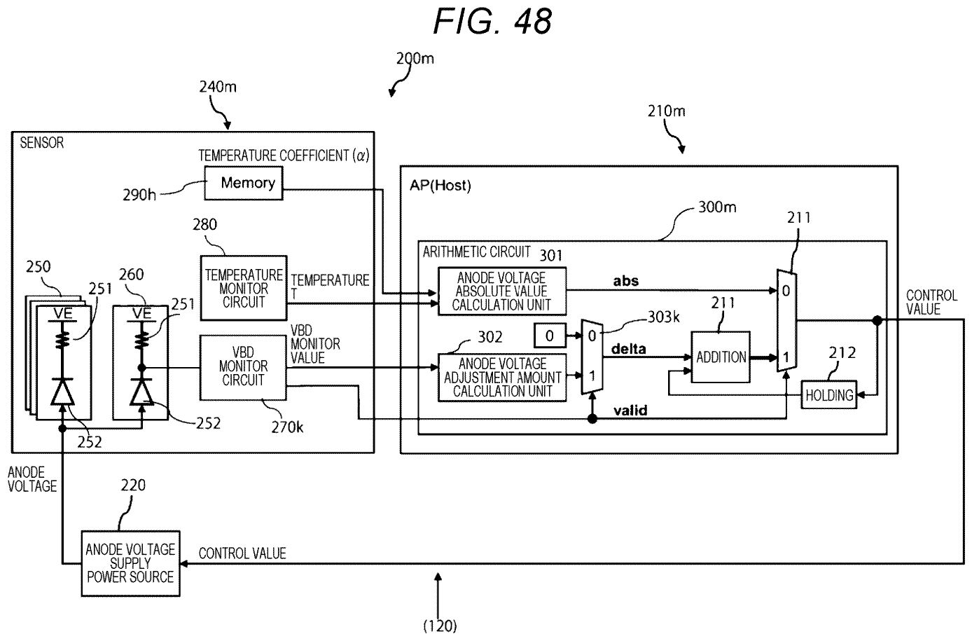

FIG. 48 is a block diagram illustrating a configuration example of a photodetection element 200 according to the second modification of the sixth embodiment. The ranging module is different from the ranging module 100 according to the first modification of the sixth embodiment in that a control circuit 210m according to the second modification of the sixth embodiment is separated from a pixel array unit 240m. As described above, the control circuit 210m is separated from the pixel array unit 240h, so that the configuration of the pixel array unit 240m can be made more versatile.

### Seventh Embodiment

A ranging module 100 according to a seventh embodiment is different from the ranging module 100 according to the sixth embodiment (see FIG. 45) in that a pixel array unit 240n further includes a VBD temporal change amount calculation unit 303. Hereinafter, differences from the ranging module 100 according to the sixth embodiment will be described below.

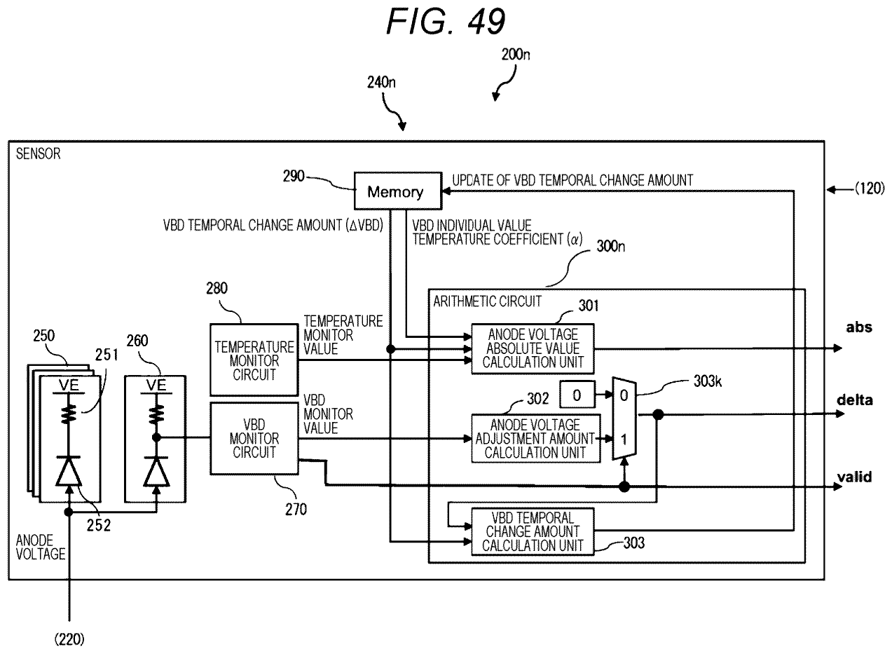

FIG. 49 is a block diagram illustrating a configuration example of an optical pixel array unit 240n in the seventh embodiment of the present technology. As illustrated in FIG. 49, an arithmetic circuit 300n further includes the VBD temporal change amount calculation unit 303. The VBD temporal change amount calculation unit 303 has the same configuration as the VBD temporal change amount calculation unit 303 according to the second embodiment.

According to the present embodiment, the VBD temporal change amount calculation unit 303 stores the adjustment value delta (see Expression (3)) in the first control in the storage unit 290 as the VBD temporal change amount ΔVBD(T0). Then, the control circuit 210 controls the anode potential of the photodiode 252 at the start of driving by the corrected anode potential abs2 in Expression (6) including the VBD temporal change amount ΔVBD(T0). Therefore, it is possible to suppress the deviation between the bottom potential Vbtm and the target potential Vtarget due to the temporal change of the photodiode 252. As described above, according to the present embodiment, in addition to the effect of the ranging module 100 according to the sixth embodiment, there is also an effect equivalent to that of the ranging module 100 according to the second embodiment.

### Eighth Embodiment

A ranging module 100 according to an eighth embodiment is different from the ranging module 100 according to the second modification of the sixth embodiment in that a part of an arithmetic circuit 300m (see FIG. 48) according to the second modification of the sixth embodiment is configured in the pixel array unit 240, and a control circuit 210p further includes a VBD temporal change amount calculation unit 303. Hereinafter, differences from the ranging module 100 according to the second modification of the sixth embodiment will be described below.

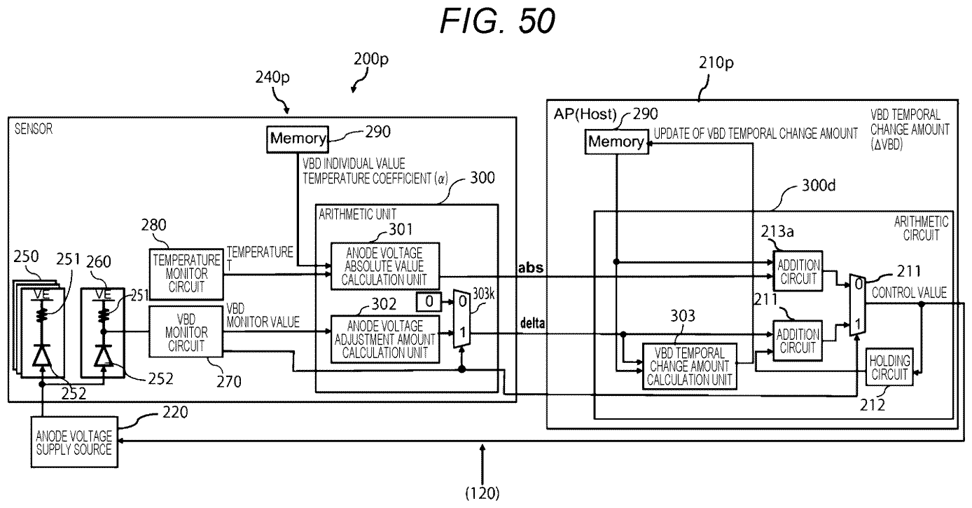

FIG. 50 is a block diagram illustrating the configuration example of a photodetection element 200p according to the eighth embodiment of the present technology.

As illustrated in FIG. 50, the control circuit 210p further includes an addition circuit 213a, a storage unit 292, and a VBD temporal change amount calculation unit 303. The VBD temporal change amount calculation unit 303 has the same configuration as the VBD temporal change amount calculation unit 303 according to the second embodiment.

According to the present embodiment, the VBD temporal change amount calculation unit 303 stores the adjustment value delta (see Expression (3)) in the first control in the storage unit 292 as the VBD temporal change amount ΔVBD(T0). Then, the addition circuit 213a calculates the corrected anode potential abs2 in Expression (6) including the VBD temporal change amount ΔVBD(T0). Then, a control circuit 210q controls the anode potential of the photodiode 252 at the start of driving. Therefore, it is possible to suppress the deviation between the bottom potential Vbtm and the target potential Vtarget due to the temporal change of the photodiode 252. As described above, according to the present embodiment, in addition to the effect of the ranging module 100 according to the second modification of the sixth embodiment, there is also an effect equivalent to that of the ranging module 100 according to the second embodiment.

### Ninth Embodiment

A ranging module 100 according to a ninth embodiment is different from the ranging module 100 (see FIG. 45) according to the sixth embodiment in that a plurality of temperature monitor circuits 280 and a plurality of VBD monitor circuits 270g according to the sixth embodiment are configured. Hereinafter, differences from the ranging module 100 according to the sixth embodiment will be described below.

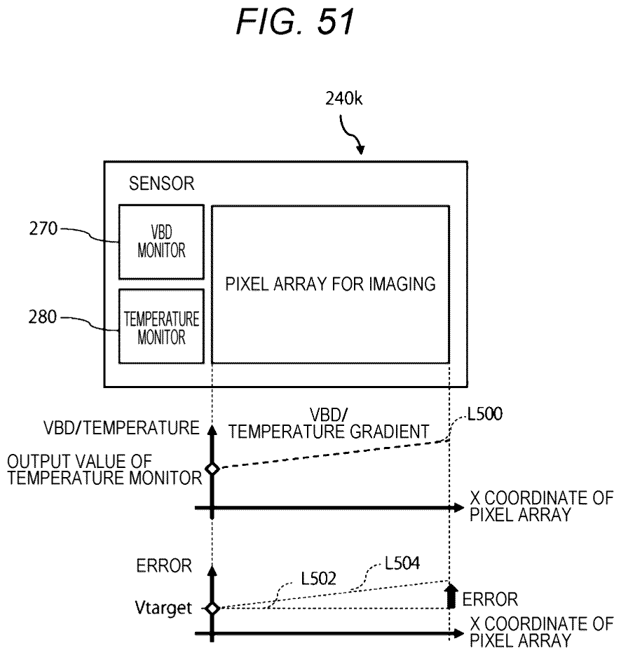

FIG. 51 is a diagram illustrating an arrangement example of the temperature monitor circuit 280 and the VBD monitor circuit 270g according to the sixth embodiment. (a) of the drawing is a diagram schematically illustrating a plan view of the pixel array unit 240k.
(b) of the drawing is a diagram illustrating a temperature change L500 in the pixel array unit 240k. The vertical axis represents the temperature, and the horizontal axis represents the position of the temperature monitor circuit 280 and the distance to the temperature monitor circuit 280.
(c) of the drawing is a diagram illustrating a relationship between the error of the target potential Vatrget and the temperature change L500. The vertical axis represents an error of the target potential Vatrge, and the horizontal axis represents the position of the temperature monitor circuit 280 and the distance to the temperature monitor circuit 280. In (c) of the drawing, a line L502 indicates the target potential Vatrget, and indicates the position variation of an error L504.

As illustrated in FIG. 51, as the distance between the temperature monitor circuit 280 and the VBD monitor circuit 270 increases, the measurement error of the temperature becomes larger, and the error of the anode potential abs in Expression (2) becomes larger.

Therefore, in a pixel array unit 240p according to the present embodiment, two monitor pixel circuits 260 are arranged at positions equidistant in the column direction from the midpoint in the row direction (horizontal direction) of the pixel array unit 240p. Furthermore, the temperature monitor circuits 280a and 280b are arranged at symmetrical positions in the row direction from the midpoint.

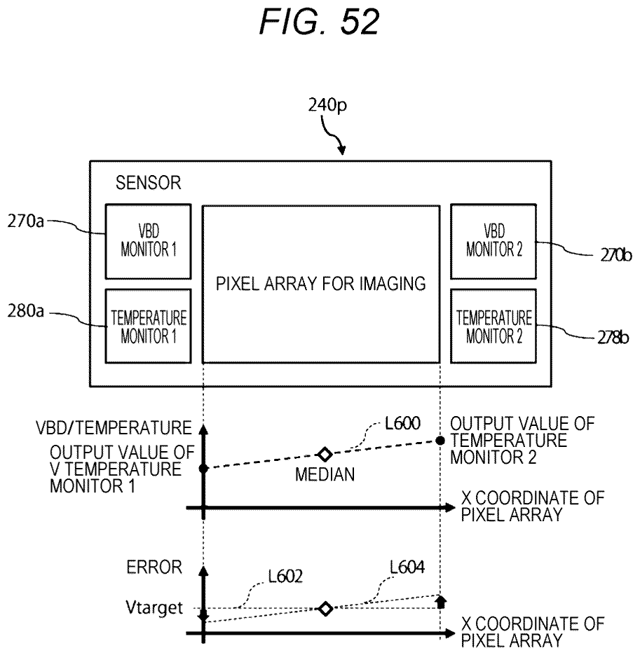

FIG. 52 is a diagram illustrating an arrangement example of the temperature monitor circuits 280a and 280b and the VBD monitor circuits 270a and 270b according to the ninth embodiment. (a) of the drawing is a diagram schematically illustrating a plan view of the pixel array unit 240k. The VBD monitor circuits 270a and 270b have, for example, a configuration equivalent to that of the VBD monitor circuit 270g (see FIG. 45).
(b) of the drawing is a diagram illustrating a temperature change L600 in the pixel array unit 240k. The vertical axis represents the temperature, and the horizontal axis represents the position in the pixel array unit 240k.
(c) of the drawing is a diagram illustrating a relationship between an error of the target potential Vatrget and a temperature change. The vertical axis represents an error of the target potential Vatrge, and the horizontal axis represents the position of the temperature monitor circuit 280 and the distance to the temperature monitor circuit 280. In (c) of the drawing, a line L602 indicates the target potential Vatrget, and indicates the position variation of an error L604.

As illustrated in (a) and (b) of the drawing, the temperature monitor circuit 280 is configured at the midpoint of the pixel array unit 240k. Therefore, the median of the temperature monitor circuits 280a and 280b corresponds to the temperature of the temperature monitor circuit 280. Therefore, as illustrated in (c) of the drawing, by using the median of the temperature monitor circuits 280a and 280b, the error of the anode potential abs in Expression (2) also approaches 0. In the drawing, the temperature change L500 in the temperature pixel array unit 240k is illustrated. The vertical axis represents the temperature, and the horizontal axis represents the position of the temperature monitor circuit 280 and the distance to the temperature monitor circuit 280.

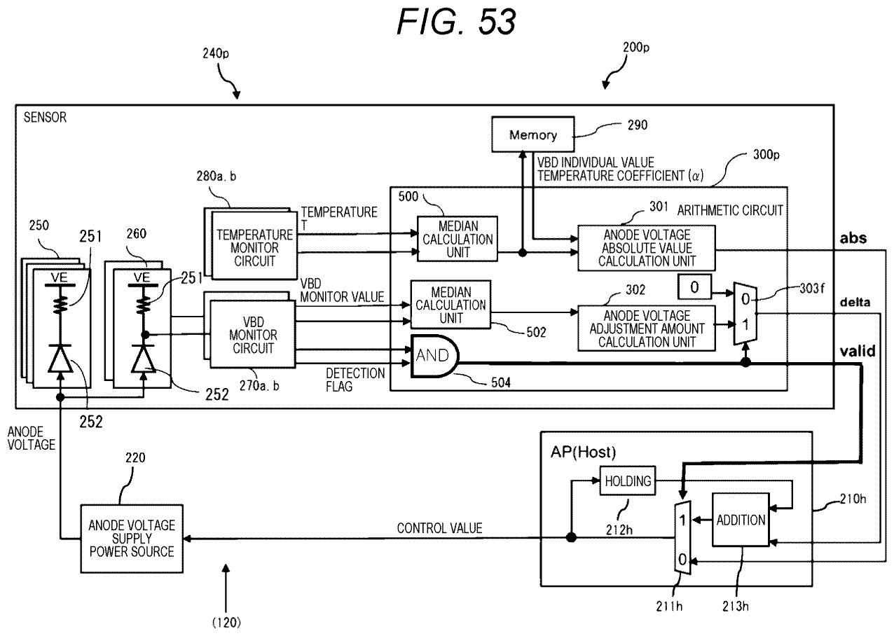

FIG. 53 is a diagram illustrating an imaging example in the pixel array unit 240p according to the ninth embodiment. The pixel array unit is different from the pixel array unit 240k (see FIG. 45) according to the sixth embodiment in further including a plurality of VBD monitor circuits 270a and 270b, a plurality of temperature monitor circuits 280a and 280b, a plurality of median calculation units 500 and 502, a median calculation unit 502, and an AND circuit 504. The median calculation unit 500 calculates the median of the output values of the temperature monitor circuits 280a and 280b. Similarly, the median calculation unit 502 calculates the median of the output values of the VBD monitor circuits 270a and 270b. Furthermore, the AND circuit 504 outputs AND of the detection flags of the VBD monitor circuits 270a and 270b.

According to the present embodiment, the two monitor pixel circuits 260 are arranged at positions equidistant in the column direction from the midpoint in the row direction (horizontal direction) of the pixel array unit 240p. Furthermore, the plurality of temperature monitor circuits 280a and 280b is arranged symmetrically in the row direction from the midpoint. Therefore, the median calculation unit 500 can detect the temperature corresponding to the position of the monitor pixel circuit 260 by calculating the midpoint of the temperatures output from the temperature monitor circuits 280a and 280b, and can control the anode potential Va using the temperature with higher accuracy. Furthermore, the median calculation unit 502 can suppress the temperature deviation by calculating the midpoint of the bottom potentials Vbtm output from the VBD monitor circuits 270a and 270b, and can control the anode potential Va with higher accuracy.

### Tenth Embodiment

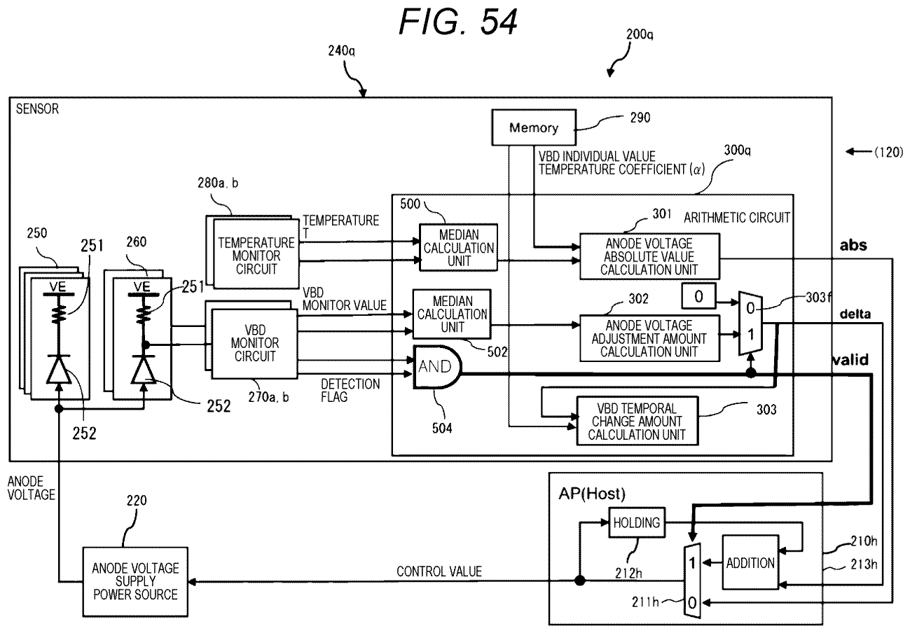

A ranging module 100 according to a tenth embodiment is different from the ranging module 100 according to the tenth embodiment (see FIG. 54) in that a pixel array unit 240q further includes the VBD temporal change amount calculation unit 303. Hereinafter, differences from the ranging module 100 according to the ninth embodiment will be described below.

FIG. 54 is a block diagram illustrating a configuration example of the pixel array unit 240q in the tenth embodiment of the present technology. As illustrated in FIG. 54, an arithmetic circuit 300q further includes the VBD temporal change amount calculation unit 303. The VBD temporal change amount calculation unit 303 has the same configuration as the VBD temporal change amount calculation unit 303 according to the second embodiment.

According to the present embodiment, the VBD temporal change amount calculation unit 303 stores the adjustment value delta (see Expression (3)) in the first control in the storage unit 290 as the VBD temporal change amount ΔVBD(T0). Then, the control circuit 210 controls the anode potential of the photodiode 252 at the start of driving by the corrected anode potential abs2 in Expression (6) including the VBD temporal change amount ΔVBD(T0). Therefore, it is possible to suppress the deviation between the bottom potential Vbtm and the target potential Vtarget due to the temporal change of the photodiode 252. As described above, according to the present embodiment, in addition to the effect of the ranging module 100 according to the tenth embodiment, there is also an effect equivalent to that of the ranging module 100 according to the second embodiment.

### Eleventh Embodiment

A ranging module 100 according to an eleventh embodiment is different from the ranging module 100 (see FIG. 32) according to the fourth embodiment in that a plurality of temperature monitor circuits 280 and a plurality of VBD monitor circuits 270g are configured. Hereinafter, differences from the ranging module 100 according to the fourth embodiment will be described below.

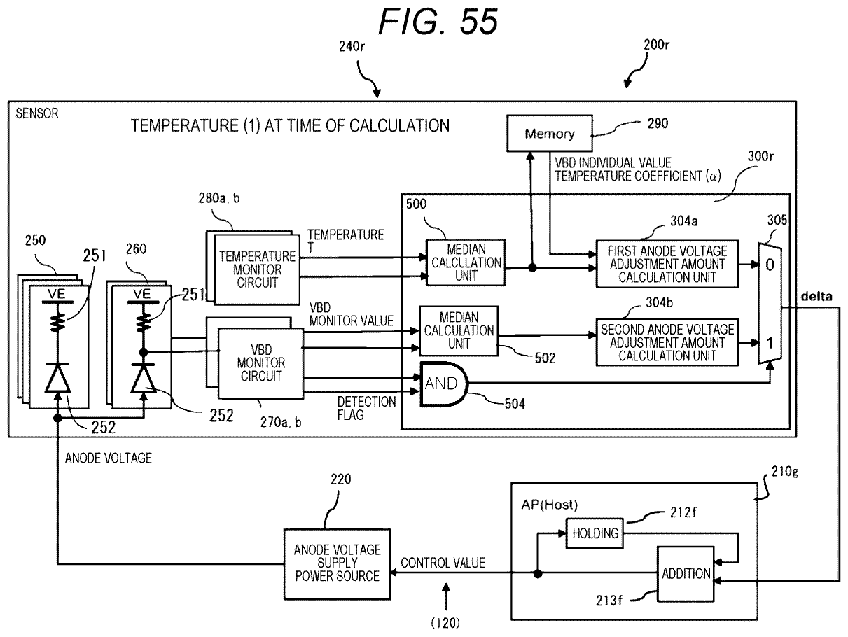

FIG. 55 is a block diagram illustrating a configuration example of a pixel array unit 240r in the eleventh embodiment of the present technology. As illustrated in FIG. 55, the pixel array unit is different from a pixel array unit 240g (see FIG. 32) according to the fourth embodiment in further including a plurality of VBD monitor circuits 270a and 270b, a plurality of temperature monitor circuits 280a and 280b, a plurality of median calculation units 500 and 502, a median calculation unit 502, and an AND circuit 504. The plurality of VBD monitor circuits 270a and 270b, the plurality of temperature monitor circuits 280a and 280b, the plurality of median calculation units 500 and 502, the median calculation unit 502, and the AND circuit 504 have the same configuration as the pixel array unit 240p (see FIG. 53) according to the tenth embodiment.

According to the present embodiment, the two monitor pixel circuits 260 are arranged at positions equidistant in the column direction from the midpoint in the row direction (horizontal direction) of the pixel array unit 240p. Furthermore, the plurality of temperature monitor circuits 280a and 280b is arranged symmetrically in the row direction from the midpoint. Therefore, the median calculation unit 500 can detect the temperature corresponding to the position of the monitor pixel circuit 260 by calculating the midpoint of the temperatures output from the temperature monitor circuits 280a and 280b, and can control the anode potential Va using the temperature with higher accuracy. Furthermore, the median calculation unit 502 can suppress the temperature deviation by calculating the midpoint of the bottom potentials Vbtm output from the VBD monitor circuits 270a and 270b, and can control the anode potential Va with higher accuracy. Moreover, the present embodiment also has an effect equivalent to that of the ranging module 10 according to the fourth embodiment.

### Application Example

The technology according to the present disclosure can be applied to various products. For example, the technology according to the present disclosure may also be implemented as a device mounted on any kind of mobile body such as an automobile, an electric automobile, a hybrid electric automobile, a motorcycle, a bicycle, a personal mobility, an airplane, a drone, a ship, a robot, a construction machine, an agricultural machine (tractor), or the like.

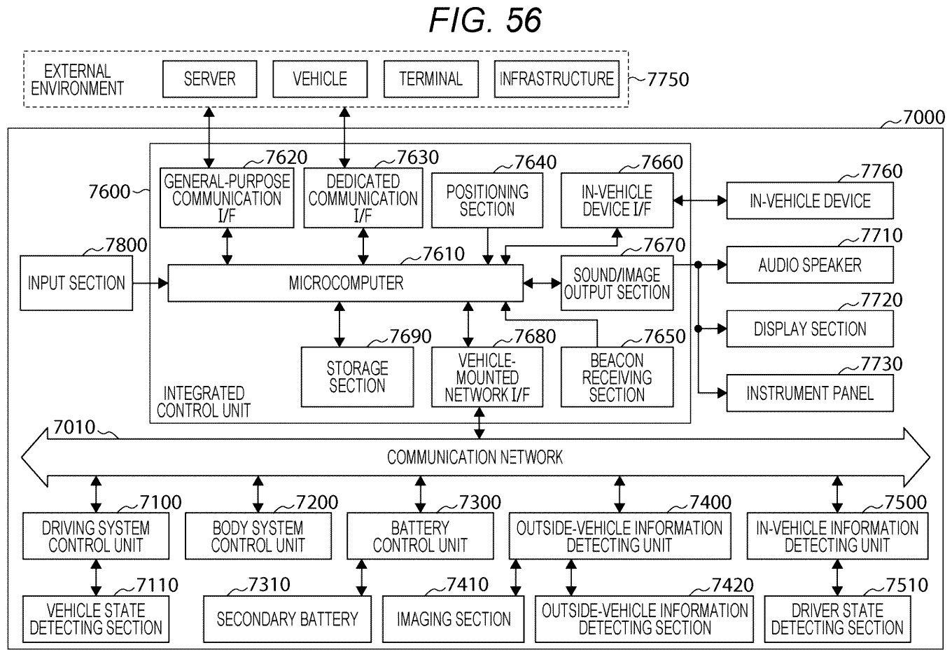

FIG. 56 is a block diagram illustrating a schematic configuration example of a vehicle control system 7000 as an example of a mobile body control system to which the technology of the present disclosure is applied. The vehicle control system 7000 includes a plurality of electronic control units connected to each other via a communication network 7010. In the example illustrated in FIG. 56, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. In FIG. 56, a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690 are illustrated as a functional configuration of the integrated control unit 7600. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

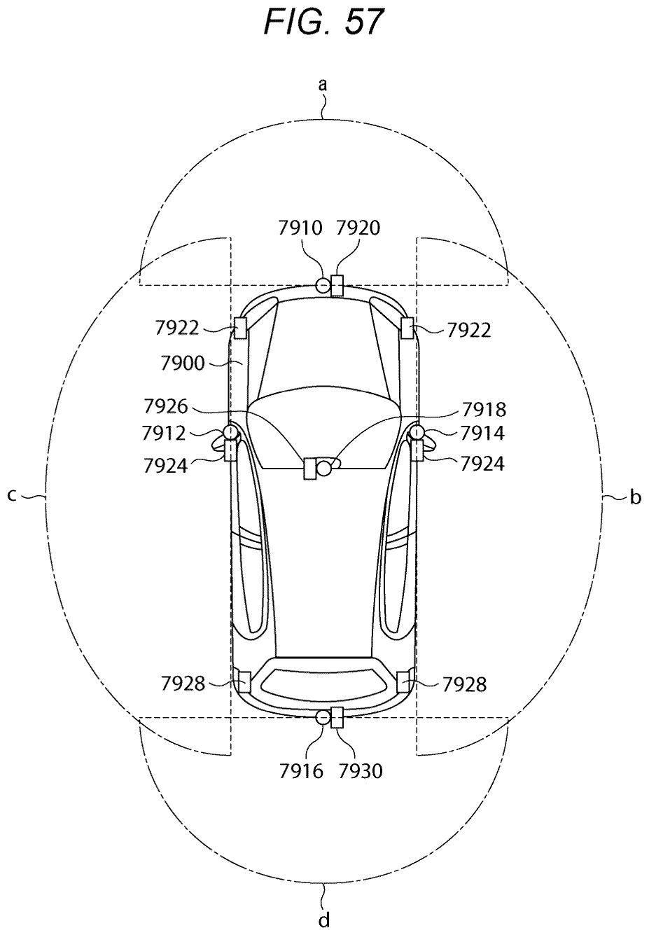

Here, FIG. 57 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 57 illustrates an example of the imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Referring back to FIG. 56, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or o the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 56, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 56, at least two control units connected through the communication network 7010 may be integrated as one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for implementing each function of the ranging module 100 according to the present embodiment described with reference to FIG. 1 can be implemented in any of the control units or the like. Furthermore, a computer-readable recording medium in which such a computer program is stored can be provided. The recording medium is, for example, a magnetic disk, an optical disk, a magneto-optical disk, a flash memory, or the like. Furthermore, the computer program described above may be distributed via, for example, a network without using a recording medium.

In the vehicle control system 7000 described above, the ranging module 100 according to the present embodiments described with reference to FIG. 1 can be applied to the integrated control unit 7600 of the application example illustrated in FIG. 56. For example, the ranging module 100 corresponds to the outside-vehicle information detecting section 7420. For example, the outside-vehicle information detecting section 7420 controls the anode potential of the photodiode 252 according to the temperature T of the photodiode 252 in the ranging module 100. Therefore, temperature fluctuation of the anode potential in the photodiode 252 can be suppressed, and the bottom potential Vbtm of the photodiode 252 can be controlled to a predetermined target potential Vtarget. Furthermore, the anode-cathode voltage VEX at the time of breakdown becomes constant regardless of the temperature, and a decrease in distance measurement accuracy is suppressed.

Note that the present technology may have the following configurations.
(1)
A photodetection element including:
a photodiode that photoelectrically converts incident light and outputs a photocurrent; and
a control circuit that performs control to change a potential of one end of the photodiode according to a temperature related to the photodiode.
(2)
The photodetection element according to (1), in which
the control circuit supplies a lower potential to an anode of the photodiode as the temperature is higher.
(3)

The photodetection element according to (2), in which
the photodiode is a SPAD operable in a Geiger mode,
the photodetection element further includes a resistor having one end connected to a cathode of the photodiode, and
a predetermined potential is supplied to an other end of the resistor.
(4)
The photodetection element according to (1), further including:
a temperature detection circuit that detects the temperature, in which
the control circuit controls the potential according to the temperature detected by the temperature detection circuit.
(5)
The photodetection element according to (4), further including:
a resistor having one end connected to a cathode of the photodiode, in which
control is performed in:
a first mode of controlling the potential according to the temperature; and
a second mode of supplying a lower potential to an anode of the photodiode as a bottom potential of the cathode is higher when the photocurrent flows through the resistor.
(6)
The photodetection element according to (5), in which
the potential is controlled in the first mode up to a predetermined number of times after supplying the potential to the anode of the photodiode is stopped.
(7)
The photodetection element according to (5), in which
the control circuit controls the potential in the second mode after the potential is controlled in the first mode.
(8)
The photodetection element according to (5), in which
the control circuit controls the potential in the first mode in a case where a predetermined potential in the cathode cannot be detected.
(9)
The photodetection element according to (5), further including:
an arithmetic circuit that calculates the potential according to the temperature, in which
the control circuit controls the potential on the basis of a calculation result of the arithmetic circuit.
(10)
The photodetection element according to (9), in which
the arithmetic circuit calculates the potential according to a predetermined coefficient and the temperature.
(11)
The photodetection element according to (10), in which
the arithmetic circuit calculates the potential also on the basis of a difference value between an initial bottom potential of the cathode, which is a potential when control in the second mode has started, and a target potential.
(12)
The photodetection element according to (11), in which
the arithmetic circuit calculates the potential on the basis of a fluctuation of the temperature per predetermined time.
(13)
The photodetection element according to (12), further including:
a detection circuit that detects a minimum value of the cathode when the photocurrent flows through the resistor as the bottom potential and supplies the detected minimum value to the arithmetic circuit.
(14)
The photodetection element according to (13), in which
the detection circuit includes a smoothing circuit that performs smoothing calculation including a predetermined number of the bottom potentials before imaging, and
a predetermined number of times of imaging in the first mode corresponds to a predetermined number before the imaging.
(15)
The photodetection element according to (14), in which
the predetermined number of times of imaging in the first mode is one at a time of activation.
(16)
The photodetection element according to (15), further including:
a pixel array unit in which a plurality of pixel circuits each including the resistor and the photodiode is arranged in a two-dimensional matrix, in which
at least two of the temperature detection circuits are configured at different positions of an element in which the pixel array unit is configured, and
the control circuit performs control to change a potential of one end of each photodiode in a plurality of pixel circuits on the basis of each temperature detected by each of the temperature detection circuits.
(17)
The photodetection element according to (16), further including:
a pixel array unit in which a plurality of pixel circuits each including the resistor and the photodiode is arranged in a two-dimensional matrix, in which
each of at least two pixel circuits among the plurality of pixel circuits includes the detection circuit, and
the control circuit performs control to change a potential of one end of each photodiode in a plurality of pixel circuits on the basis of each potential detected by the detection circuit.
(18)
The photodetection element according to (17), in which
the arithmetic circuit and the control circuit are integrally configured in a same element.
(19)
The photodetection element according to (18), further including:
a power source circuit that supplies a potential of the anode of each of the plurality of pixel circuits, in which
the control circuit controls the power source circuit.
(20)
The electronic apparatus, including:
a photodetection element according to (1); and
a light emitting unit configured to emit measurement light synchronized with a timing of changing the potential.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Smartphone
200 to 200r Photodetection element
210 to 210h Control circuit
220 Anode voltage supply power source
251 Resistor
270 VBD monitor circuit
280 Temperature monitor circuit
300 to 300r Arithmetic circuit

1. A photodetection element comprising:
a photodiode that photoelectrically converts incident light and outputs a photocurrent; and
a control circuit that performs control to change a potential of one end of the photodiode according to a temperature related to the photodiode.

2. The photodetection element according to claim 1, wherein
the control circuit supplies a lower potential to an anode of the photodiode as the temperature is higher.

3. The photodetection element according to claim 2, wherein
the photodiode is a SPAD operable in a Geiger mode,
the photodetection element further comprises a resistor having one end connected to a cathode of the photodiode, and
a predetermined potential is supplied to an other end of the resistor.

4. The photodetection element according to claim 1, further comprising:
a temperature detection circuit that detects the temperature, wherein
the control circuit controls the potential according to the temperature detected by the temperature detection circuit.

5. The photodetection element according to claim 4, further comprising:
a resistor having one end connected to a cathode of the photodiode, wherein
control is performed in:
a first mode of controlling the potential according to the temperature; and
a second mode of supplying a lower potential to an anode of the photodiode as a bottom potential of the cathode is higher when the photocurrent flows through the resistor.

6. The photodetection element according to claim 5, wherein
the potential is controlled in the first mode up to a predetermined number of times after supplying the potential to the anode of the photodiode is stopped.

7. The photodetection element according to claim 5, wherein
the control circuit controls the potential in the second mode after the potential is controlled in the first mode.

8. The photodetection element according to claim 5, wherein
the control circuit controls the potential in the first mode in a case where a predetermined potential in the cathode cannot be detected.

9. The photodetection element according to claim 5, further comprising:
an arithmetic circuit that calculates the potential according to the temperature, wherein
the control circuit controls the potential on a basis of a calculation result of the arithmetic circuit.

10. The photodetection element according to claim 9, wherein
the arithmetic circuit calculates the potential according to a predetermined coefficient and the temperature.

11. The photodetection element according to claim 10, wherein
the arithmetic circuit calculates the potential also on a basis of a difference value between an initial bottom potential of the cathode, which is a potential when control in the second mode has started, and a target potential.

12. The photodetection element according to claim 11, wherein
the arithmetic circuit calculates the potential on a basis of a fluctuation of the temperature per predetermined time.

13. The photodetection element according to claim 12, further comprising:
a detection circuit that detects a minimum value of the cathode when the photocurrent flows through the resistor as the bottom potential and supplies the detected minimum value to the arithmetic circuit.

14. The photodetection element according to claim 13, wherein
the detection circuit includes a smoothing circuit that performs smoothing calculation including a predetermined number of the bottom potentials before imaging, and
a predetermined number of times of imaging in the first mode corresponds to a predetermined number before the imaging.

15. The photodetection element according to claim 14, wherein
the predetermined number of times of imaging in the first mode is one at a time of activation.

16. The photodetection element according to claim 15, further comprising:
a pixel array unit in which a plurality of pixel circuits each including the resistor and the photodiode is arranged in a two-dimensional matrix, wherein
at least two of the temperature detection circuits are configured at different positions of an element in which the pixel array unit is configured, and
the control circuit performs control to change a potential of one end of each photodiode in a plurality of pixel circuits on a basis of each temperature detected by each of the temperature detection circuits.

17. The photodetection element according to claim 16, further comprising:
a pixel array unit in which a plurality of pixel circuits each including the resistor and the photodiode is arranged in a two-dimensional matrix, wherein
each of at least two pixel circuits among the plurality of pixel circuits includes the detection circuit, and
the control circuit performs control to change a potential of one end of each photodiode in a plurality of pixel circuits on a basis of each potential detected by the detection circuit.

18. The photodetection element according to claim 17, wherein
the arithmetic circuit and the control circuit are integrally configured in a same element.

19. The photodetection element according to claim 18, further comprising:
a power source circuit that supplies a potential of the anode of each of the plurality of pixel circuits, wherein
the control circuit controls the power source circuit.

20. The electronic apparatus, comprising:
a photodetection element according to claim 1; and
a light emitting unit configured to emit measurement light synchronized with a timing of changing the potential.
